(19) United States
(12) Patent Application Publication
(10) Pub. No.: US 2022/0185659 A1
(43) Pub. Date: Jun. 16, 2022

(54) IMAGING DEVICE

(71) Applicant: SONY SEMICONDUCTOR SOLUTIONS CORPORATION, KANAGAWA (JP)

(72) Inventors: HIDENOBU TSUGAWA, KANAGAWA (JP); KENICHI NISHIZAWA, KANAGAWA (JP); KIICHI ISHIKAWA, KANAGAWA (JP)

(21) Appl. No.: 17/437,464

(22) PCT Filed: Mar. 2, 2020
(86) PCT No.: PCT/JP2020/008597

§ 371 Date: Sep. 9, 2021

(30) Foreign Application Priority Data
Mar. 25, 2019 (JP) 2019-056134

(51) Int. Cl. B81B 7/02; H01L 27/146; H04N 5/232

(52) U.S. Cl. CPC B81B 7/02; H01L 27/14636; H01L 24/13; H04N 5/23245; H04N 5/23258

(57) ABSTRACT

There is provided an imaging device including: an imaging element provided with a photoelectric converter for each pixel, and having a light-receiving surface and a non-light-receiving surface opposed to the light-receiving surface; and an electric element including a support substrate and a floating section, the support substrate provided on side of the non-light-receiving surface of the imaging element and opposed to the imaging element, and the floating section provided between the support substrate and the imaging element, and disposed with a gap interposed between the floating section and each of the support substrate and the imaging element.

### TECHNICAL FIELD

The present disclosure relates to an imaging device including an imaging element.

### BACKGROUND ART

An imaging device such as a camera system includes, together with an imaging element, an MEMS (Micro Electro Mechanical Systems) such as an acceleration sensor and a gyro sensor. This makes it possible to perform image stabilization and the like.

For example, PTL 1 describes a substrate including a portion serving as an imaging element and a portion serving as an MEMS.

### CITATION LIST

### Patent Literature

PTL 1: Japanese Unexamined Patent Application Publication No. 2012-4540

### SUMMARY OF THE INVENTION

It is desired to reduce an occupied area of such an imaging device.

It is therefore desirable to provide an imaging device that makes it possible to reduce an occupied area thereof.

An imaging device according to an embodiment of the present disclosure includes: an imaging element provided with a photoelectric converter for each pixel, and having a light-receiving surface and a non-light-receiving surface opposed to the light-receiving surface; and an electric element including a support substrate and a floating section, the support substrate provided on side of the non-light-receiving surface of the imaging element and opposed to the imaging element, and the floating section provided between the support substrate and the imaging element, and disposed with a gap interposed between the floating section and each of the support substrate and the imaging element.

In the imaging device according to the embodiment of the present disclosure, the support substrate of the electric element including the floating section is provided opposed to the imaging element. That is, the electric element is stacked on the imaging element. Thus, an occupied area of the imaging device is substantially equal to an area of one of the imaging element and the electric element.

### BRIEF DESCRIPTION OF DRAWINGS

FIG. 1 (A) is a schematic cross-sectional view of a configuration of a main part of an imaging device according to a first embodiment of the present disclosure, and (B) is a schematic view of an example of a planar configuration of an MEMS illustrated in (A) of FIG. 1.

FIG. 2 is a block diagram illustrating an example of a functional configuration of the imaging device illustrated in FIG. 1.

FIG. 3A is a schematic cross-sectional view of one process of a method of manufacturing an imaging element illustrated in (A) of FIG. 1.

FIG. 3B is a schematic cross-sectional view of a process subsequent to FIG. 3A.

FIG. 3C is a schematic cross-sectional view of a process subsequent to FIG. 3B.

FIG. 3D is a schematic cross-sectional view of a process subsequent to FIG. 3C.

FIG. 3E is a schematic cross-sectional view of a process subsequent to FIG. 3D.

FIG. 4 (A) is a schematic cross-sectional view of one process of a method of manufacturing the MEMS illustrated in (A) of FIG. 1, and (B) is a schematic view of a planar configuration of the process illustrated in (A) of FIG. 4.

FIG. 5 (A) is a schematic cross-sectional view of a process subsequent to (A) of FIG. 4, and (B) is a schematic view of a planar configuration of the process illustrated in (A) of FIG. 5.

FIG. 6A is a schematic cross-sectional view of a process subsequent to FIG. 3E.

FIG. 6B is a schematic cross-sectional view of a process subsequent to FIG. 6A.

FIG. 6C is a schematic cross-sectional view of a process subsequent to FIG. 6B.

FIG. 7 is a schematic cross-sectional view of a configuration of a main part of an imaging device according to a comparative example.

FIG. 8 is a schematic cross-sectional view of a configuration of a main part of an imaging device according to a modification example 1.

FIG. 9 is a schematic cross-sectional view of a configuration of a main part of an imaging device according to a modification example 2.

FIG. 10 is a schematic cross-sectional view of a configuration of a main part of an imaging device according to a modification example 3.

FIG. 11 is a block diagram illustrating an example of a functional configuration of an imaging device according to a modification example 4.

FIG. 12 is a flowchart illustrating an example of an operation of the imaging device illustrated in FIG. 11.

FIG. 13 is a block diagram illustrating an example of a functional configuration of an imaging device according to a modification example 5.

FIG. 14 is a flowchart illustrating an operation of the imaging device illustrated in FIG. 13.

FIG. 15 is a block diagram illustrating an example of a functional configuration of an imaging device according to a modification example 6.

FIG. 16 is a flowchart illustrating an example of an operation of the imaging device illustrated in FIG. 15.

FIG. 17 is a schematic perspective view of an example of a configuration of an imaging device (an MEMS) according to a modification example 7.

FIG. 18 is a schematic view of an example of a planar configuration of the MEMS illustrated in FIG. 17.

FIG. 19A is a schematic view of a cross-sectional configuration taken along a line A-A′ illustrated in FIG. 18.

FIG. 19B is a schematic view of a cross-sectional configuration taken along a line B-B′ illustrated in FIG. 18.

FIG. 20A is a schematic cross-sectional view of one process of a method of manufacturing the MEMS illustrated in FIG. 17 and the like.

FIG. 20B is a schematic view of another cross-sectional configuration of the process illustrated in FIG. 20A.

FIG. 21A is a schematic cross-sectional view of a process subsequent to FIG. 20A.

FIG. 21B is a schematic view of another cross-sectional configuration of the process illustrated in FIG. 21A.

FIG. 22A is a schematic cross-sectional view of a process subsequent to FIG. 21A.

FIG. 22B is a schematic view of another cross-sectional configuration of the process illustrated in FIG. 22A.

FIG. 23A is a schematic cross-sectional view of a process subsequent to FIG. 22A.

FIG. 23B is a schematic view of another cross-sectional configuration of the process illustrated in FIG. 23A.

FIG. 24 is a block diagram illustrating an example of a functional configuration of the imaging device illustrated in FIG. 17.

FIG. 25 is a block diagram illustrating another example of the functional configuration of the imaging device illustrated in FIG. 17.

FIG. 26 is a schematic cross-sectional view of a configuration of a main part of an imaging device according to a second embodiment of the present disclosure.

FIG. 27A is a schematic view of an example of a planar configuration of an imaging element illustrated in FIG. 26.

FIG. 27B is a schematic view of an example of a planar configuration of an infrared detector illustrated in FIG. 26.

FIG. 28 is a schematic view of another example of a cross-sectional configuration of the imaging device illustrated in FIG. 26.

FIG. 29A is a schematic view of an example of a planar configuration of an imaging element illustrated in FIG. 28.

FIG. 29B is a schematic view of an example of a planar configuration of an infrared detector illustrated in FIG. 28.

FIG. 30 is a block diagram depicting an example of a schematic configuration of an in-vivo information acquisition system.

FIG. 31 is a view depicting an example of a schematic configuration of an endoscopic surgery system.

FIG. 32 is a block diagram depicting an example of a functional configuration of a camera head and a camera control unit (CCU).

FIG. 33 is a block diagram depicting an example of schematic configuration of a vehicle control system.

FIG. 34 is a diagram of assistance in explaining an example of installation positions of an outside-vehicle information detecting section and an imaging section.

### MODES FOR CARRYING OUT THE INVENTION

Hereinafter, some embodiments of the present disclosure are described in detail with reference to the drawings. It is to be noted that description is given in the following order.

1. First Embodiment (An imaging device in which an imaging element and a MEMS are stacked)
2. Modification Example 1 (An example in which a logic chip is provided with an external coupling terminal)
3. Modification Example 2 (An example in which the MEMS is provided with an external coupling terminal)
4. Modification Example 3 (An example in which a relay substrate is provided between the imaging element and the MEMS)
5. Modification Example 4 (An example including an imaging determination section)
6. Modification Example 5 (An example including an imaging mode selector)
7. Modification Example 6 (An example including an imaging mode switching determination section)
8. Modification Example 7 (An example in which the MEMS serves as a magnetic sensor)
9. Second Embodiment (An imaging device in which an imaging element and an infrared detector are stacked)

### 10. Practical Application Examples

### First Embodiment

### (Configuration of Imaging Device 1)

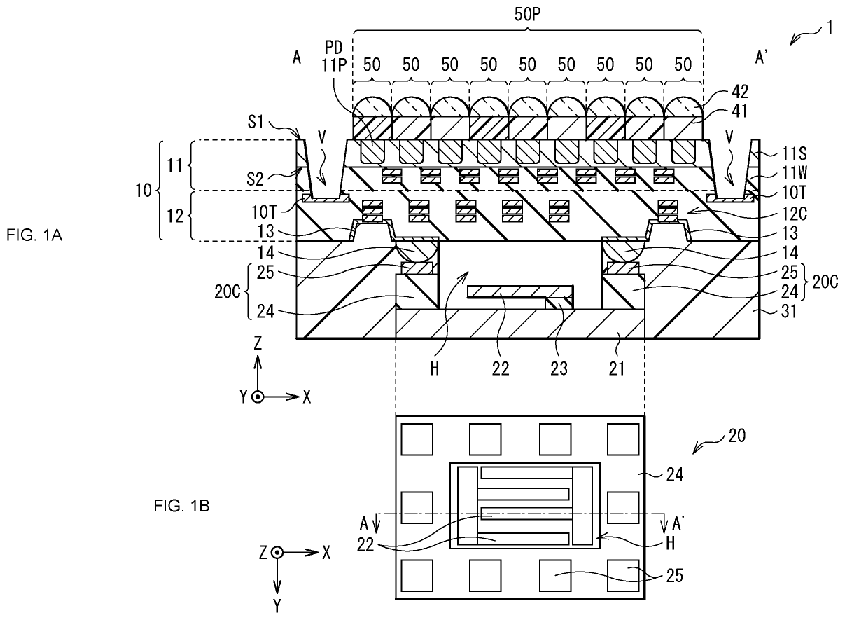

(A) and (B) of FIG. 1 schematically illustrate a configuration of a main part of a solid-state imaging device (an imaging device 1) according to a first embodiment of the present disclosure. (A) of FIG. 1 illustrates a cross-sectional configuration of the imaging device 1. The imaging device 1 includes an imaging element 10 and a MEMS 20. (B) of FIG. 1 illustrates an example of a planar configuration of the MEMS 20 illustrated in (A) of FIG. 1. Here, the MEMS 20 corresponds to a specific example of an electric element of the present disclosure.

The imaging element 10 is, for example, a back-illuminated CMOS (Complementary Metal Oxide Semiconductor) image sensor. The imaging element 10 includes a pixel section 50P that includes a plurality of pixels 50. The imaging element 10 has a stacked structure of a sensor chip 11 and a logic chip 12. The sensor chip 11 includes a semiconductor substrate 11S and a multilayer wiring layer 11W. The logic chip 12 is opposed to the semiconductor substrate 11S with the multilayer wiring layer 11W interposed therebetween. The imaging element 10 includes a color filter 41 and an on-chip lens 42 on side of a light-receiving surface (a light-receiving surface S1 to be described later) of the sensor chip 11. The semiconductor substrate 11S corresponds to a specific example of a first semiconductor substrate of the present disclosure.

The MEMS 20 is a microelectromechanical element, that is, a so-called micromachine. The MEMS 20 detects, for example, an inertial force, vibration, or the like, and specific examples thereof include a gyro sensor, an acceleration sensor, and the like. The MEMS 20 includes, for example, a support substrate 21, a movable section 22, a fixing section 23, a surrounding wall 24, and a pad electrode 25.

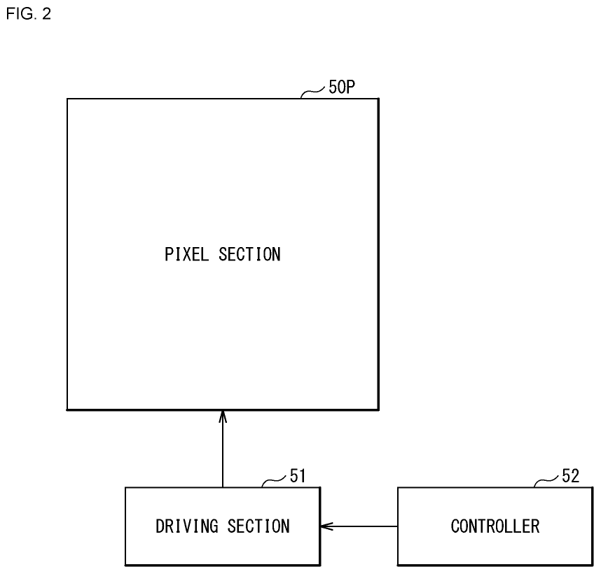

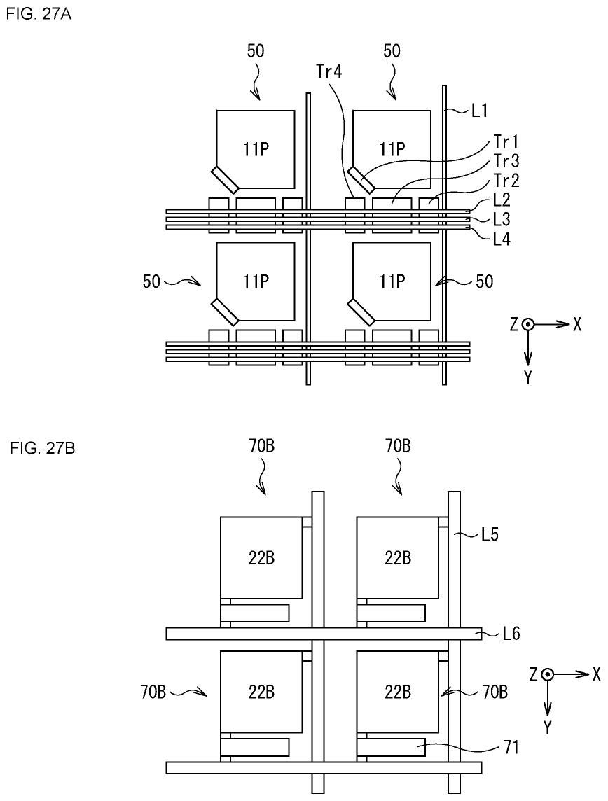

FIG. 2 illustrates an example of a functional configuration of the imaging device 1. The imaging device 1 includes, for example, the pixel section 50P, a driving section 51, and a controller 52. In the pixel section 50P, for example, the plurality of pixels 50 (FIG. 1) is arranged in a matrix. The pixel section 50P is wired with pixel drive lines (pixel drive lines L2, L3, L4, and the like in FIG. 27A and the like to be described later) provided along a row direction for respective pixel rows of the pixel arrangement, and is wired with vertical signal lines (a vertical signal line L1 and the like in FIG. 27A to be described later) provided along a column direction for respective pixel columns of the pixel arrangement. The pixel drive lines each transmit a drive signal to each of the pixels 50. The drive signal is outputted from the driving section 51 row by row. The controller 52 inputs a control signal to the driving section 51. The driving section 51 transmits the drive signal to the pixel section 50P on the basis of the control signal inputted from the controller 52.

A specific configuration of the imaging device 1 is described below with use of (A) and (B) of FIG. 1.

The sensor chip 11 is a chip having a photoelectric conversion function, and includes a sensor circuit. The sensor chip 11 includes the multilayer wiring layer 11W and the semiconductor substrate 11S in order from side of the logic chip 12. The semiconductor substrate 11S of the sensor chip 11 has the light-receiving surface S1 and a non-light-receiving surface S2 opposed to the semiconductor substrate 11S. In The sensor chip 11, for example, the multilayer wiring layer 11W is provided on side of the non-light-receiving surface S2 of the semiconductor substrate 11S. The semiconductor substrate 11S provided between the multilayer wiring layer 11W and the color filter 41 includes, for example, a silicon (Si) substrate. The semiconductor substrate 11S is provided with a PD (Photo Diode) 11P for each of the pixels 50. The PD 11P corresponds to a specific example of a photoelectric converter of the present disclosure. The multilayer wiring layer 11W provided between the semiconductor substrate 11S and the logic chip 12 includes an interlayer insulating film and a plurality of wiring lines. The interlayer insulating film separates the plurality of wiring lines of the multilayer wiring layer 11W from each other, and includes, for example, silicon oxide (SiO) or the like. The plurality of wiring lines provided in the multilayer wiring layer 11W is included in a sensor circuit, for example.

The logic chip 12 provided opposed to the sensor chip 11 includes, for example, a logic circuit 12C that is electrically coupled to the PD 11P of the sensor chip 11. For example, the PD 11P is electrically coupled to the logic circuit 12C through the sensor circuit of the multilayer wiring layer 11W. The logic chip 12 includes, for example, a semiconductor substrate, and a plurality of MOS (Metal Oxide Semiconductor) transistors is provided in a p-type semiconductor well region of the semiconductor substrate. The logic circuit 12C is configured using the plurality of MOS transistors. The semiconductor substrate includes, for example, a silicon substrate. The multilayer wiring layer 11W of the sensor chip 11 and the logic chip 12 (the logic circuit 12C) are electrically coupled to each other. The multilayer wiring layer 11W and the logic chip 12 are coupled to each other by, for example, metal bonding such as Cu—Cu bonding. Alternatively, the multilayer wiring layer 11W and the logic chip 12 may be coupled to each other with use of a through electrode. The semiconductor substrate of the logic chip 12 corresponds to a specific example of a second semiconductor substrate of the present disclosure.

Of the logic chip 12, a surface (hereinafter referred to as a back surface of the logic chip 12) on side opposite to a surface bonded to the sensor chip 11 (the multilayer wiring layer 11W) is provided with a rewiring layer 13 and a microbump 14. The rewiring layer 13 is provided to couple the logic circuit 12C of the logic chip 12 and the microbump 14 to each other. The microbump 14 is provided to electrically couple the rewiring layer 13 and the MEMS 20 (specifically, the pad electrode 25) to each other. That is, the imaging element 10 is electrically coupled to the MEMS 20 through the microbump 14 and the rewiring layer 13.

The color filter 41 and the on-chip lens 42 are provided in this order on the light-receiving surface S1 of the semiconductor substrate 11S. The color filter 41 is, for example, one of a red (R) filter, a green (G) filter, a blue (B) filter, and a white filter (W), and is provided for each of the pixels 50, for example. These color filters 41 are provided in a regular color arrangement (e.g., a Bayer arrangement). Providing such color filters 41 allows the imaging element 10 to acquire light reception data of colors corresponding to the color arrangement.

The on-chip lens 42 on the color filter 41 is provided, for each of the pixels 50, at a position opposed to the PD 11P of the sensor chip 11. Light having entered the on-chip lens 42 is concentrated on the PD 11P for each of the pixels 50. A lens system of this on-chip lens 42 is set at a value corresponding to a pixel size. Examples of a lens material of the on-chip lens 42 include an organic material, a silicon oxide film (SiO), and the like.

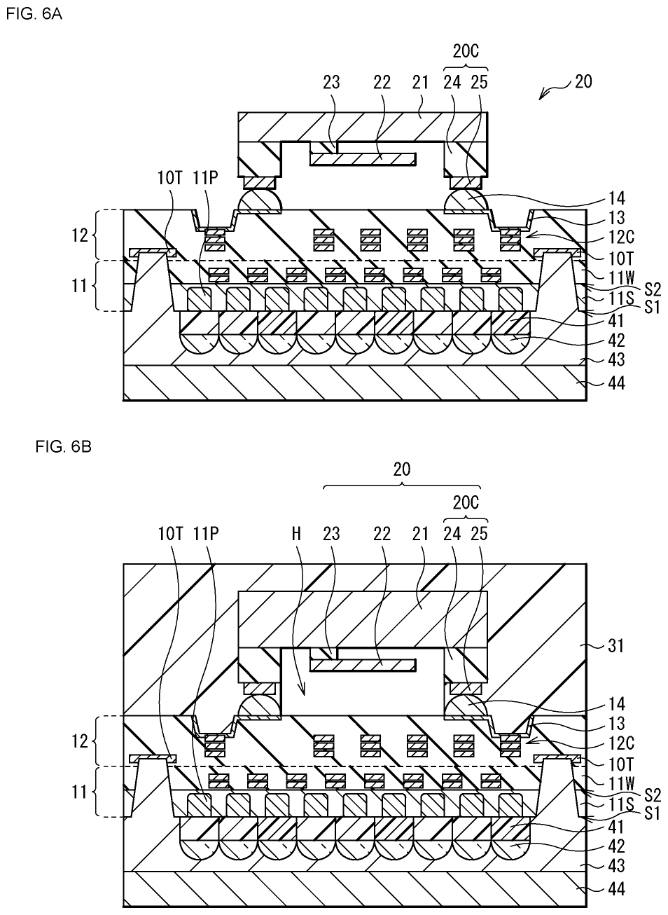

In the present embodiment, the MEMS 20 is provided opposed to such an imaging element 10. That is, in the imaging device 1, the imaging element 10 and the MEMS 20 are provided to be stacked. As described in detail later, this makes it possible to reduce an occupied area, as compared with a case where the imaging element and the MEMS are provided side by side on the same substrate (an imaging device 100 in FIG. 7 to be described later).

The MEMS 20 is opposed to the sensor chip 11 with the logic chip 12 interposed therebetween. In other words, the MEMS 20 is provided on side of the non-light-receiving surface S2 of the imaging element 10. The support substrate 21 of the MEMS 20 is opposed to the logic chip 12 (the imaging element 10). The movable section 22 is provided between the support substrate 21 and the logic chip 12. Here, the movable section 22 corresponds to a specific example of a floating section of the present disclosure. The fixing section 23 is provided between the movable section 22 and the support substrate 21, and a portion of the movable section 22 is fixed to the support substrate 21 by the fixing section 23. A plurality of coupling sections 20C is provided around the movable section 22 in a plan (an XY plane in (B) of FIG. 1) view. Each of the plurality of coupling sections 20C couples the support substrate 21 and the microbump 14 (the imaging element 10) to each other in a direction (a Z direction in (A) of FIG. 1) of stacking the imaging element 10 and the MEMS 20. The coupling sections 20C each include, for example, the surrounding wall 24 and the pad electrode 25 in order from side of the support substrate 21. A resin layer 31 is provided around the MEMS 20.

A substrate area of the support substrate 21 is, for example, smaller than chip areas of the sensor chip 11 and the logic chip 12 of the imaging element 10. The support substrate 21 is disposed, for example, at a position corresponding to a middle portion of the imaging element 10 in a plan view. The support substrate 21 includes, for example, a silicon (Si) substrate or the like. The support substrate 21 is provided with a MEMS circuit (not illustrated).

A hollow section H is provided between the support substrate 21 and the imaging element 10 (the logic chip 12). The hollow section H is space surrounded by the support substrate 21, the imaging element 10, and the coupling section 20C. Here, the movable section 22 is provided in the hollow section H provided between the support substrate 21 and the imaging element 10. That is, one side of the movable section 22 is sealed with the imaging element 10; therefore, it is not necessary to separately provide a member for packaging the MEMS 20. This makes it possible to reduce cost.

The movable section 22 is disposed in the hollow section H with a gap interposed between the movable section 22 and each of the support substrate 21 and the imaging element 10 (the logic chip 12). For example, a plurality of movable sections 22 extending in a predetermined direction (e.g., an X-axis direction in (A) and (B) of FIG. 1) is provided in the hollow section H. For example, one end or another end of each of the linearly extending movable sections 22 is fixed to the support substrate 21 by the fixing section 23. (B) of FIG. 1 illustrates four movable sections 22, and two of the movable sections 22 each have the one end fixed to the support substrate 21 by the fixing section 23. The other two movable sections each have the other end fixed to the support substrate 21 by the fixing section 23. The movable sections 22 each are displaced in response to, for example, an inertial force, vibration, or the like received by the imaging device 1. The movable sections 22 include, for example, metal such as aluminum. The movable sections 22 may include polysilicon or the like. Alternatively, the movable sections 22 may be formed by processing the support substrate 21. The fixing section 23 provided between the movable section 22 and the support substrate 21 includes, for example, silicon oxide (SiO) or the like.

The surrounding wall 24 is provided to be spaced apart from the one end and the other end of each of the movable sections 22, and is disposed in proximity to a periphery of the support substrate 21. In a plan view, for example, the surrounding wall 24 is provided continuously in a frame shape to surround the movable sections 22. A height (a size in a Z-axis direction in (A) of FIG. 1) of the surrounding wall 24 is sufficiently larger than a height of the fixing section 23. Accordingly, the pad electrode 25 on the surrounding wall 24 is disposed at a position closer in the Z-axis direction to the imaging element 10 than the movable sections 22. The surrounding wall 24 includes, for example, silicon oxide (SiO) or the like. A bottom surface (a surface on side of the support substrate 21) of the surrounding wall 24 is in contact with the support substrate 21.

A plurality of pad electrodes 25 is provided on a top surface of the surrounding wall 24 to be spaced apart from each other. For example, as with the surrounding wall 24, the pad electrodes 25 are disposed at positions opposed to the proximity to the periphery of the support substrate 21, and the plurality of pad electrodes 25 are preferably spaced apart from each other at substantially equal intervals. The intervals between the plurality of pad electrode 25 are made substantially equal, thereby forming a plurality of coupling sections 20C, which each include the pad electrode 25 and the surrounding wall 24, around the movable sections 22 at substantially equal intervals. This hinders entry of the resin layer 31, which surrounds the MEMS 20, into the hollow section H. For example, the plurality of pad electrodes 25 is disposed at positions corresponding to corners and sides of the support substrate 21 having a square shape. Some of the plurality of pad electrodes 25 may be dummy electrodes that do not serve as electrodes. The dummy electrode is used, for example, to form the coupling sections 20C around the movable section 22 with an equal feeling.

A top surface (a surface on side of the imaging element 10) of each of the plurality of pad electrodes 25 is coupled to the logic chip 12 through the microbump 14 and the rewiring layer 13. A bottom surface of each of the plurality of pad electrodes 25 is coupled to a MEMS circuit (not illustrated) through a wiring line, a via, and the like inside the surrounding wall 24, for example. The top surface of each of the pad electrodes 25 is disposed at a position closer in the Z-axis direction to the imaging element 10 than a top surface of the movable section 22. This forms a gap between the imaging element 10 (the logic chip 12) and the movable section 22.

The resin layer 31 is provided around such a MEMS 20, specifically to surround the support substrate 21 and the coupling sections 20C. The resin layer 31 is provided to seal the MEMS 20 with the imaging element 10, and is provided in a region overlapping a portion, which is widened from the MEMS 20, of the imaging element 10 in a plan view. A thickness (a size in the Z direction in (B) of FIG. 1) of the resin layer 31 is substantially equal to a thickness of the MEMS 20. The resin layer 31 is provided outside a region (the hollow section H) surrounded by the plurality of coupling sections 20C.

The imaging device 1 performs input and output of signals to and from outside through an external coupling terminal 10T, for example. The external coupling terminal 10T is provided in proximity to the surface bonded to the sensor chip 11 of the logic chip 12, for example. A coupling hole V that reaches the external coupling terminal 10T is provided outside the pixel section 50P in the sensor chip 11.

### (Method of Manufacturing Imaging Device 1)

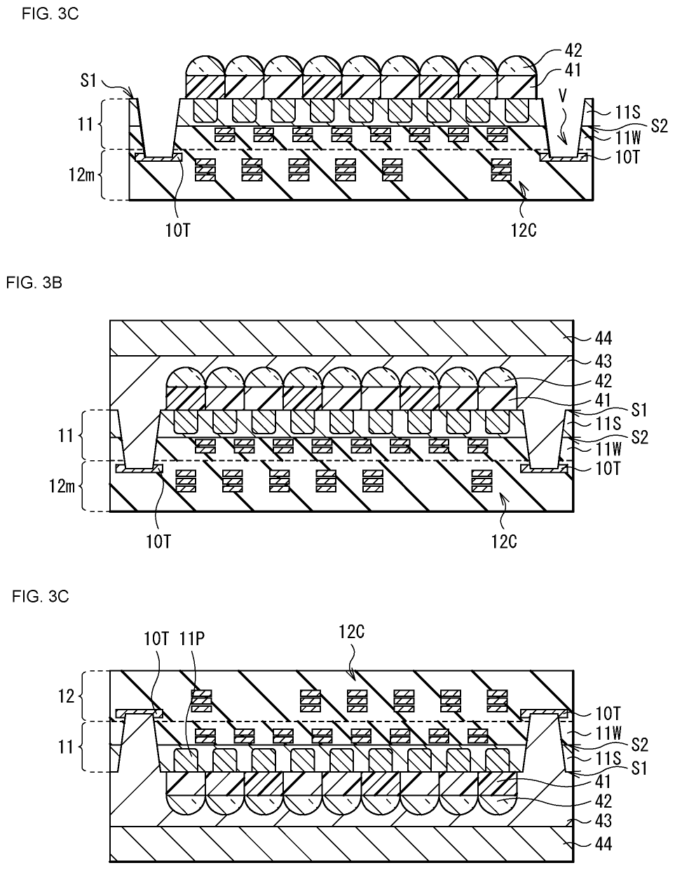

It is possible to manufacture such an imaging device 1 as follows, for example (FIG. 3A to FIG. 6C).

First, after the sensor chip 11 is formed, the color filter 41 and the on-chip lens 42 are formed on the light-receiving surface S1 of the semiconductor substrate 11S.

Next, as illustrated in FIG. 3A, the multilayer wiring layer 11W of the sensor chip 11 is bonded to a logic substrate 12m. The logic substrate 12m includes the logic circuit 12C, and the logic chip 12 is formed with use of the logic substrate 12m in a later process.

After the sensor chip 11 is bonded to the logic substrate 12m, as illustrated in FIG. 3B, a temporary substrate 44 is bonded to the logic substrate 12m with use of a filling layer 43. The temporary substrate 44 is disposed to be opposed to the logic substrate 12m with the color filter 41 and the on-chip lens 42 interposed therebetween. The filling layer 43 is formed with use of, for example, a resin material or the like.

Substantially, as illustrated in FIG. 3C, the logic substrate 12m is polished from side of one surface thereof to form the logic chip 12. For example, a surface, on side opposite to the surface bonded to the sensor chip 11, of the logic substrate 12m is polished by, for example, a grinder or the like. This causes the logic substrate 12m to be thinned, thereby forming the logic chip 12.

After the logic chip 12 is formed, as illustrated in FIGS. 3D and 3E, the rewiring layer 13 and the microbump 14 are formed in this order on the back surface of the logic chip 12. The rewiring layer 13 is formed to be coupled to a wiring line in the logic chip 12 through a coupling hole from the back surface of the logic chip 12 to the inside of the logic chip 12, for example. The microbump 14 is formed on the rewiring layer 13. Thus, the imaging element 10 is formed.

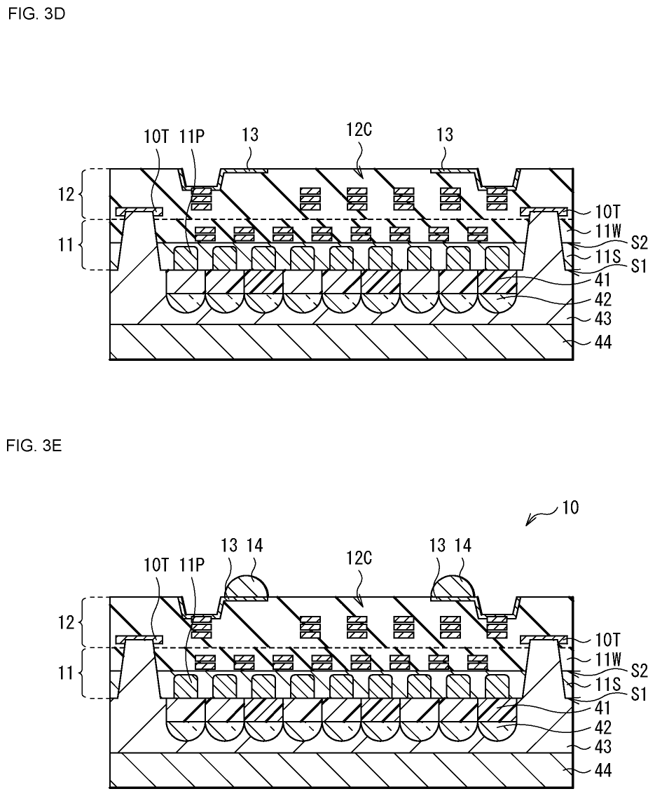

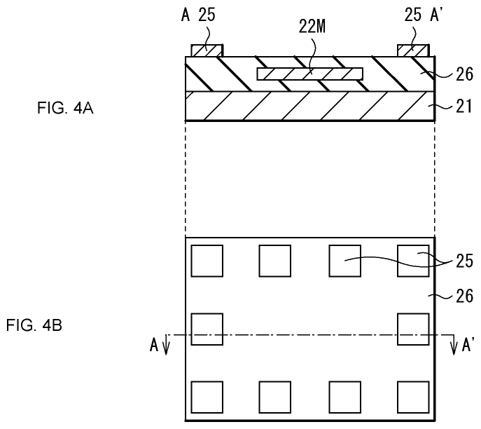

Next, a method of manufacturing the MEMS 20 stacked on the imaging element 10 is described with use of FIGS. 4 and 5. (A) of FIG. 4 and (A) of FIG. 5 are cross-sectional views of each process of manufacturing the MEMS 20, and (B) of FIG. 4 and (B) of FIG. 5 are respectively plan views corresponding to the processes illustrated in (A) of FIG. 4 and (A) of FIG. 5. (A) of FIG. 4 and (A) of FIG. 5 illustrate cross-sectional configurations taken along a line A-A′ illustrated in (B) of FIG. 4 and (B) of FIG. 5.

First, as illustrated in (A) of FIG. 4 and (A) of FIG. 5, an insulating film 26, a metal film 22M, and the pad electrodes 25 are formed on the support substrate 21 including a silicon (Si) substrate, for example. The insulating film 26 is formed on, for example, the entire surface of the support substrate 21. The insulating film 26 is formed between the support substrate 21 and the metal film 22M, and is formed to cover the metal film 22M. The metal film 22M is formed in a selective region on the insulating film 26. The metal film 22M is formed in, for example, a middle portion of the support substrate 21. The movable section 22 is formed with use of the metal film 22M by a later patterning process. The movable section 22 may be formed with use of a portion of the support substrate 21. The pad electrodes 25 are formed on the insulating film 26 that covers the metal film 22M. The pad electrodes 25 are formed, for example, along corners and sides of the support substrate 21 outside a region where the metal film 22M is formed.

After the pad electrodes 25 are formed, as illustrated in (A) and (B) of FIG. 5, the metal film 22M is patterned to form the movable section 22 and remove an unnecessary portion of the insulating film 26. For example, lithography technology is used for patterning of the metal film 22M. The unnecessary portion of the insulating film 26 is removed to form the fixing section 23 between the movable section 22 and the support substrate 21 and the surrounding wall 24 around the movable section 22. After the movable section 22 and the coupling sections 20C that surround the movable section 22 are formed on the support substrate 21 in such a manner, the support substrate 21 is individualized (not illustrated). Thus, the MEMS 20 is formed.

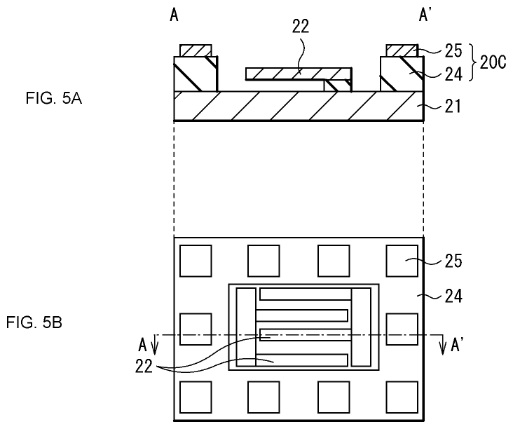

After the imaging element 10 and the MEMS 20 are formed, as illustrated in FIG. 6A, the MEMS 20 is stacked on the imaging element 10. At this time, the pad electrode 25 of the MEMS 20 is coupled to the microbump 14 of the imaging element 10.

Next, as illustrated in FIG. 6B, the resin layer 31 is formed outside the MEMS 20 (the surrounding wall 24). Thus, the movable section 22 of the MEMS 20 is sealed with the imaging element 10 to form the hollow section H between the imaging element 10 and the support substrate 21.

After the resin layer 31 is formed, as illustrated in FIG. 6C, the resin layer 31 and the support substrate 21 are polished to a desired thickness. The resin layer 31 and the support substrate 21 are polished with use of CMP (Chemical Mechanical Polishing) technology or the like, for example. Finally, the filling layer 43 and the temporary substrate 44 are peeled. It is possible to manufacture the imaging device 1 in such a manner, for example.

### (Operation of Imaging Device 1)

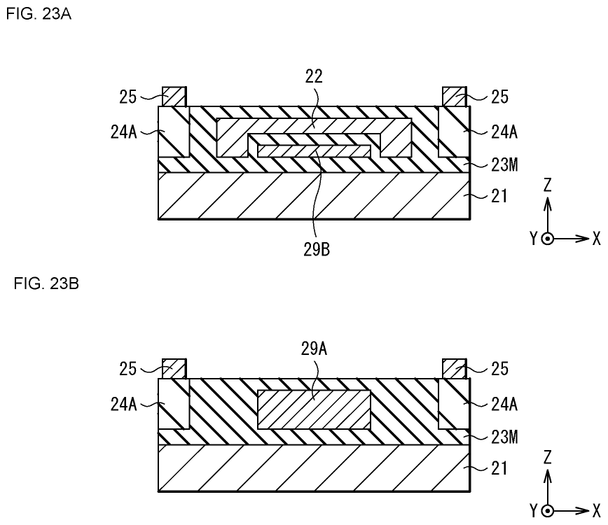

Such an imaging device 1 acquires a signal electric charge (e.g., an electron) as follows, for example. Once light passes through the on-chip lens 42, the color filter 41, and the like to enter the sensor chip 11, this light is detected (absorbed) by the PD 11P of each pixel and red, green or blue light is photoelectrically converted. Signal electric charges (e.g., electrons) of electron-hole pairs generated by the PD 11P are converted into imaging signals, and are processed by the logic circuit 12C of the logic chip 12. Meanwhile, a signal corresponding to displacement of the movable section 22 of the MEMS 20 is inputted to, for example, a signal processor (a signal processor 62 in FIG. 24 and the like to be described later).

### (Workings and Effects of Imaging Device 1)

In the present embodiment, the support substrate 21 of the MEMS 20 including the movable section 22 is provided to be opposed to the imaging element 10. That is, the MEMS 20 is stacked on the imaging element 10. This makes it possible to reduce an occupied area, as compared with a case where an imaging section and a movable section are provided side by side on the same substrate. The following describes workings and effects thereof with use of a comparative example.

FIG. 7 illustrates a schematic cross-sectional configuration of a main part of an imaging device (the imaging device 100) according to the comparative example. The imaging device 100 includes an imaging section 110 and a MEMS section 120 in one substrate (a substrate 100S). The imaging section 110 is provided with a PD (e.g., the PD 11P in FIG. 1) for each pixel, and the MEMS section 120 is provided with a movable section (e.g., the movable section 22 in FIG. 1). That is, in the imaging device 100, the imaging section 110 and the MEMS section 120 are disposed side by side on the same substrate (the substrate 100S).

In such an imaging device 100, an occupied area thereof, that is, a so-called chip area is equal to the sum of an area of the imaging section 110 and an area of the MEMS section 120. It is therefore difficult to reduce the chip area. In addition, in the imaging device 100, the substrate 100S is shared by the imaging section 110 and the MEMS section 120, which causes manufacturing processes to be susceptible to restriction, and easily decreases flexibility in design. For example, it is difficult to form a movable section including silicon (Si) in the MEMS section 120 of the imaging device 100. That is, it is difficult to mount a bulk micromachine on the imaging device 100.

In contrast, in the imaging device 1, the MEMS 20 is stacked on the imaging element 10; therefore, the occupied area (chip area) of the imaging device 1 is an area of one of the imaging element 10 and the MEMS 20. For example, in a case where the occupied area of the imaging element 10 is larger than the occupied area of the MEMS 20, the occupied area of the imaging device 1 is substantially equal to the occupied area of the imaging element 10. Accordingly, in the imaging device 1, the chip area is easily reduced, as compared with the imaging device 100.

In addition, in processes of manufacturing the imaging device 1, it is possible to stack the imaging element 10 and the MEMS 20 after each of them are formed. This makes it possible to design the MEMS 20 more freely, as compared with the imaging device 100. For example, it is possible to form the movable section 22 of the MEMS 20 by three-dimensional processing of the support substrate 21.

As described above, in the present embodiment, the MEMS 20 including the movable section 22 is provided to be stacked on the imaging element 10, which makes it possible to reduce the occupied area, as compared with a case where the imaging section 110 and the MEMS section 120 are provided side by side on the same substrate (the substrate 100S). This makes it possible to reduce the occupied area.

In addition, it is possible to stack the imaging element 10 and the MEMS 20 after forming each of the imaging element 10 and the MEMS 20. This makes it possible to reduce restrictions on the manufacturing processes and to design the MEMS 20 more freely.

Furthermore, the movable section 22 is provided in the hollow section H between the imaging element 10 and the support substrate 21; therefore, it is not necessary to separately provide a member for packaging the MEMS 20. This makes it possible to reduce cost.

In addition, the pad electrodes 25 include dummy electrodes, which makes it possible to increase the number of coupling sections 20C. This makes it possible to easily suppress entry of the resin layer 31 into the hollow section H.

In addition, the imaging element 10 and the MEMS 20 are integrated, which causes a rotation direction, a movement direction, and the like of the imaging element 10 to be coincident with a rotation direction, a movement direction, and the like of the MEMS 20. For example, in a case where a chip having an imaging function and a chip having a MEMS function are coupled to each other by a wiring substrate, the rotation directions, movement directions, and the like of them may be deviated. Accordingly, in a case where the MEMS 20 is, for example, an acceleration sensor, a gyro sensor, or the like, it is possible to perform image stabilization with higher accuracy in the imaging device 1.

In addition, in the imaging device 1, the imaging element 10 and the MEMS 20 are electrically coupled to each other by the microbump 14 and the pad electrodes 25. This eliminates the necessity of a wiring substrate and the like for electrically coupling the chip having the imaging function and the chip having the MEMS function to each other, which makes it possible to reduce a mounting area. Furthermore, it is possible to reduce cost caused by the wiring substrate and the like.

Modification examples of the embodiment described above and other embodiments are described below. In the following description, the same components as those in the embodiment described above are denoted by the same reference numerals, and description thereof is omitted as appropriate.

### Modification Example 1

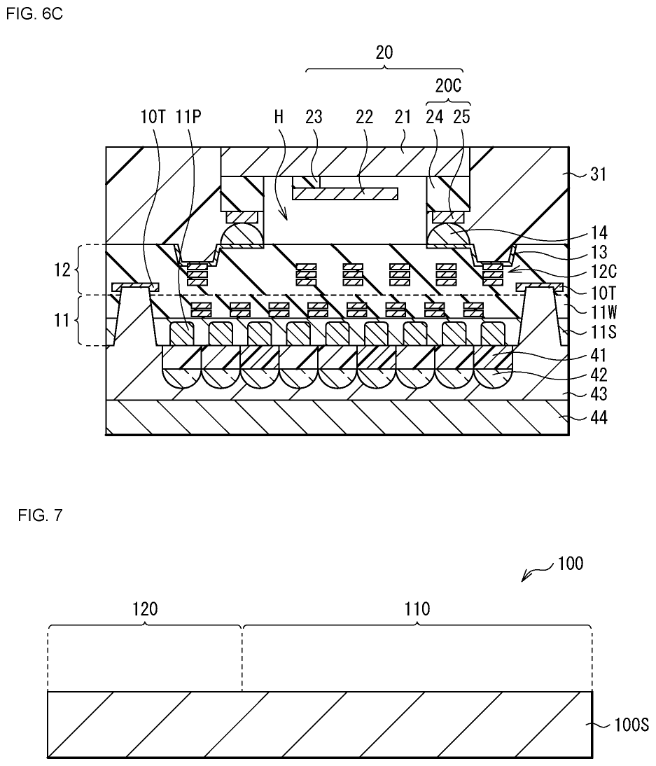

FIG. 8 illustrates a schematic cross-sectional configuration of an imaging device (an imaging device 1A) according to a modification example 1 of the first embodiment described above. In the imaging device 1A, the external coupling terminal 10T is provided on the back surface of the logic chip 12. The imaging device 1A according to the modification example 1 has a configuration similar to that of the imaging device 1 according to the first embodiment described above except for this point, and also attains similar workings and similar effects. FIG. 8 corresponds to (A) of FIG. 1 illustrating the imaging device 1.

The external coupling terminal 10T provided on the back surface of the logic chip 12 is electrically coupled to a wiring line in the logic chip 12 through a coupling via, for example. The external coupling terminal 10T is provided in a region not overlapping the MEMS 20 in a plan view, and the resin layer 31 is provided inside the external cooling terminal 10T in a plan view.

It is possible to form such an external coupling terminal 10T, for example, by the same process as the process of forming the microbump 14 (see FIG. 3E). In addition, it is sufficient if the resin layer 31 that covers the external coupling terminal 10T is removed by the process of polishing the support substrate 21 and the resin layer 31 (see FIG. 6C). It is possible to simply form the external coupling terminal 10T on the back surface of the logic chip 12 in such a manner.

Even in the present modification example, the MEMS 20 including the movable section 22 is provided to be stacked on the imaging element 10, which makes it possible to reduce the occupied area. In addition, the external coupling terminal 10T is provided on the back surface of the logic chip 12, which facilitates power supply to the logic chip 12, and the like.

### Modification Example 2

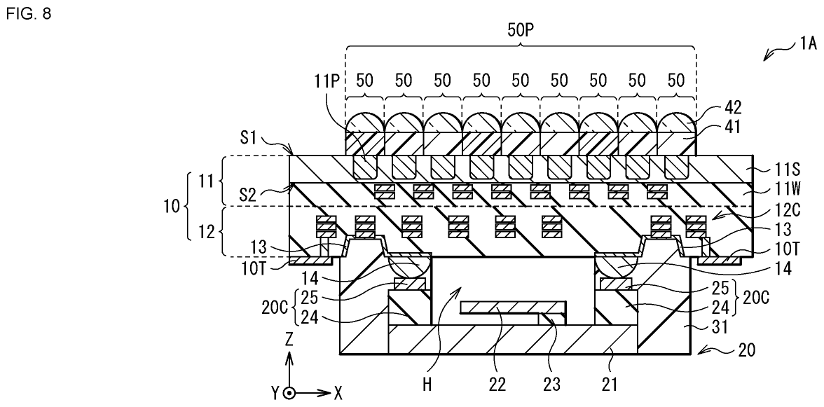

FIG. 9 illustrates a schematic cross-sectional configuration of a main part of an imaging device (an imaging device 1B) according to a modification example 2 of the first embodiment described above. In the imaging device 1B, the external coupling terminal 10T is provided on the support substrate 21 of the MEMS 20. The imaging device 1B according to the modification example 2 has a configuration similar to that of the imaging device 1 according to the first embodiment described above except for this point, and also attains similar workings and similar effects. FIG. 9 corresponds to (A) of FIG. 1 illustrating the imaging device 1.

In the imaging device 1B, the external coupling terminal 10T is provided on one surface (a surface on side opposite to a surface on side of the imaging element 10) of the support substrate 21. The external coupling terminal 10T is electrically coupled to the imaging element 10 through, for example, a coupling electrode 27 and the pad electrode 25 that are provided in the MEMS 20. The coupling electrode 27 is provided in the surrounding wall 24, for example. One surface of the coupling electrode 27 is coupled to the pad electrode 25 through a via provided in the surrounding wall 24, and another surface of the coupling electrode 27 is coupled to the external coupling terminal 10T through a via that is provided in the surrounding wall 24 and the support substrate 21. The coupling electrode 27 is provided in the same layer as the movable section 22. The pad electrode 25 electrically coupled to the coupling electrode 27 is electrically coupled to a wiring line in the logic chip 12 through the microbump 14 and the rewiring layer 13.

In a process of manufacturing the imaging device 1B, first, the coupling electrode 27 is formed by the same process as the process of forming the movable section 22. Then, after the process of polishing the support substrate 21 and the resin layer 31 (see FIG. 6C), a via is formed that reaches the coupling electrode 27 from one surface of the support substrate 21. Thereafter, the external coupling terminal 10T is formed on the one surface of the support substrate 21.

Even in the present modification example, the MEMS 20 including the movable section 22 is provided to be stacked on the imaging element 10, which makes it possible to reduce the occupied area.

### Modification Example 3

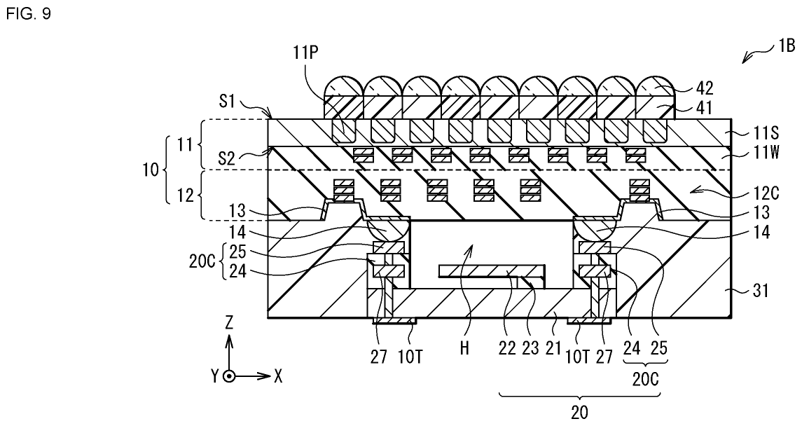

FIG. 10 illustrates a schematic cross-sectional configuration of a main part of an imaging device (an imaging device 1C) according to a modification example 3 of the first embodiment describe above. The imaging device 1C includes a relay substrate 45 between the imaging element 10 and the MEMS 20. The imaging device 1C according to the modification example 3 has a configuration similar to that of the imaging device 1 according to the first embodiment described above except for this point, and also attains similar workings and similar effects. FIG. 10 corresponds to (A) of FIG. 1 illustrating the imaging device 1.

The relay substrate 45 includes, for example, a silicon (Si) interposer substrate. In the imaging device 1C, the imaging element 10 and the MEMS 20 are electrically coupled to each other through the relay substrate 45. Specifically, the microbump 14 provided on the back surface of the logic chip 12 and a microbump 28 provided on the pad electrode 25 are electrically coupled to each other through the relay substrate 45. The microbump 14 is electrically coupled to a wiring line in the logic chip 12, and the microbump 28 is electrically coupled to the pad electrode 25.

Even in the present modification example, the MEMS 20 including the movable section 22 is provided to be stacked on the imaging element 10, which makes it possible to reduce the occupied area. In addition, the imaging element 10 and the MEMS 20 are electrically coupled to each other through the relay substrate 45; therefore, precise alignment between the microbump 14 of the imaging element 10 and the pad electrode on side of the MEMS 20 is not necessary. This makes it possible to dispose the imaging element 10 and the MEMS 20 more freely in the imaging device 1C.

### Modification Example 4

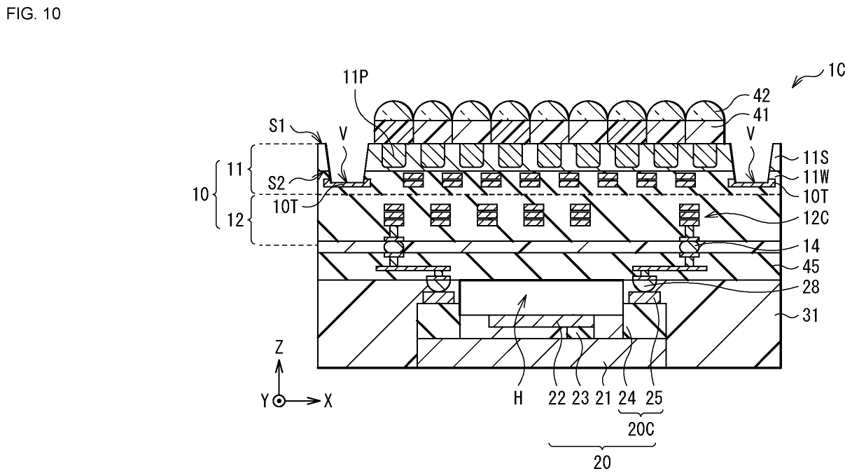

FIG. 11 illustrates a functional configuration of an imaging device (an imaging device 1D) according to a modification example 4 of the first embodiment described above. In the imaging device 1D, the controller 52 includes an imaging determination section 52A. The imaging device 1D according to the modification example 4 has a configuration similar to that of the imaging device 1 according to the first embodiment described above except for this point, and also attains similar workings and similar effects. FIG. 11 corresponds to FIG. 2 illustrating the imaging device 1.

The imaging device 1D is used, for example, for monitoring and acquires an image when the imaging device 1D detects abnormality by vibration (displacement of the movable section 22). The imaging device 1D includes a detector 61 that detects displacement of the movable section 22. The detector 61 transmits a detection signal based on the displacement of the movable section 22 to the imaging determination section 52A. The imaging determination section 52A determines, by the detection signal transmitted from the detector 61, whether or not to acquire an image. In a case where the imaging determination section 52A determines to acquire an image, a control signal is transmitted from the controller 52 to the driving section 51. The driving section 51 inputs a drive signal to each of the pixels 50 of the pixel section 50P on the basis of the control signal.

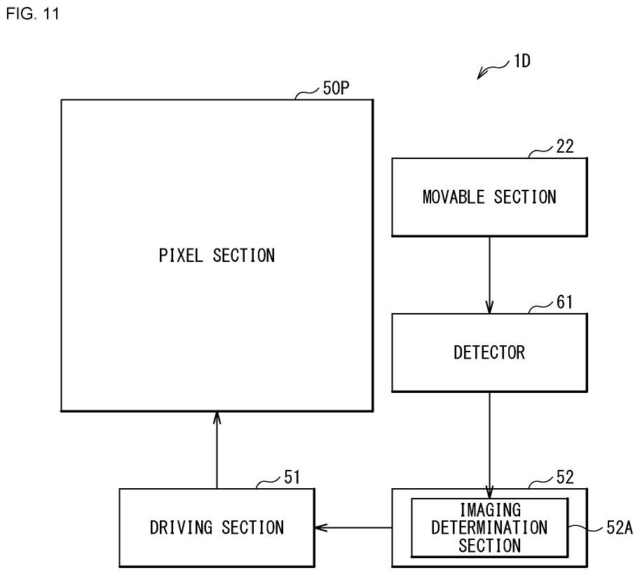

FIG. 12 illustrates an example of an operation of the imaging device 1D.

First, the detector 61 is activated (step S101). This causes the detector 61 to monitor displacement of the movable section 22. Next, the detector 61 determines whether or not the movable section 22 is displaced (step S102). When the detector 61 detects displacement of the movable section 22, a detection signal based on this displacement is inputted to the imaging determination section 52A.

The imaging determination section 52A determines, by the signal inputted from the detector 61, whether or not to perform imaging (step S103). For example, when the detector 61 detects predetermined magnitude or more of displacement, the imaging determination section 52A determines to perform imaging. When the imaging determination section 52A determines not to perform imaging, the operation returns to the step S101.

When the imaging determination section 52A determines to perform imaging, a control signal is inputted from the controller 52 to the driving section 51, and the driving section 51 inputs a drive signal to each of the pixels 50 of the pixel section 50P on the basis of the control signal (step S104). Thus, imaging is performed (step S105), and an image is acquired. After acquiring the image, a surveillant determines whether or not to perform monitoring by the imaging device 1D. When monitoring is continued to be performed, the operation returns to the step S101. When monitoring is stopped after acquiring the image, the operation of the imaging device 1D ends.

Even in the present modification example, the MEMS 20 including the movable section 22 is provided to be stacked on the imaging element 10, which makes it possible to reduce the occupied area. In addition, displacement of the movable section 22 and an imaging operation of the imaging element 10 are linked with each other, which makes it possible to suitably use the imaging device 1D for monitoring. Furthermore, the controller 52 includes the imaging determination section 52A, which makes it possible to cause the imaging element 10 to perform the imaging operation only when the detector 61 detects abnormality. This makes it possible to reduce power consumption in the imaging device 1D, as compared with a case where the imaging element 10 constantly performs the imaging operation.

### Modification Example 5

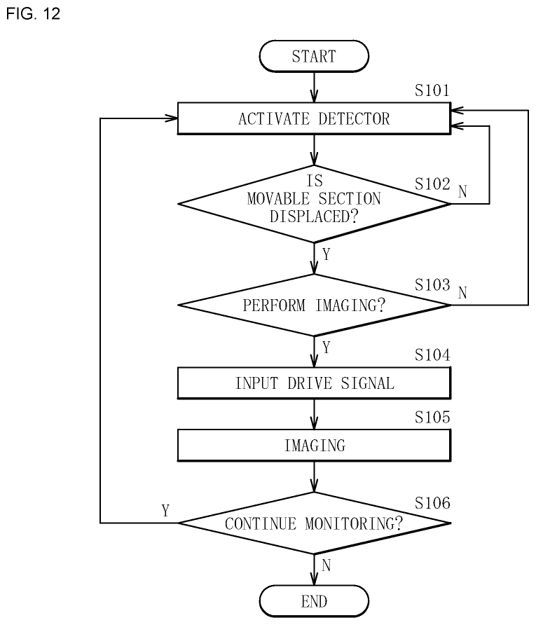

FIG. 13 illustrates a functional configuration of an imaging device (an imaging device 1E) according to a modification example 5 of the first embodiment descried above. In the imaging device 1E, the controller 52 includes the imaging determination section 52A and an imaging mode selector 52B. The imaging device 1E according to the modification example 5 has a configuration similar to that of the imaging device 1 according to the first embodiment described above except for this point, and also attains similar workings and similar effects. FIG. 13 corresponds to FIG. 2 illustrating the imaging device 1.

The imaging device 1E is used, for example, for monitoring as with the imaging device 1D described above, and includes the detector 61 that detects displacement of the movable section 22. The detector 61 transmits a detection signal based on the displacement of the movable section 22 to the imaging determination section 52A. The imaging determination section 52A determines, by the detection signal transmitted from the detector 61, whether or not to acquire an image. In a case where the imaging determination section 52A determines to acquire an image, a signal is transmitted from the imaging determination section 52A to the imaging mode selector 52B. The imaging mode selector 52B selects an optimum imaging mode corresponding to a situation on the basis of this signal or information inputted from outside. In the imaging mode selector 52B, for example, a frame rate, the number of pixels, the number of pitches, and the like are selectable. That is, the imaging mode selector 52B is able to increase the frame rate, the number of pixels, and the number of pitches. The controller 52 transmits a control signal to the driving section 51 on the basis of information about the imaging mode selected by the imaging mode selector 52B. The driving section 51 inputs a drive signal to each of the pixels 50 of the pixel section 50P on the basis of the control signal.

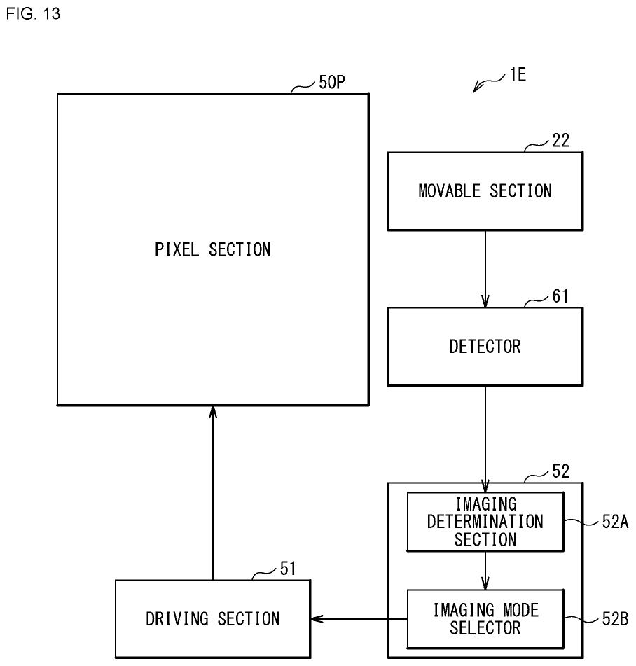

FIG. 14 illustrates an example of an operation of the imaging device 1E.

First, the detector 61 is activated (step S101). This causes the detector 61 to monitor displacement of the movable section 22. Next, the detector 61 determines whether or not the movable section 22 is displaced (step S102). When the detector 61 detects displacement of the movable section 22, a detection signal based on this displacement is inputted to the imaging determination section 52A.

The imaging determination section 52A determines, by the signal inputted from the detector 61, whether or not to perform imaging (step S103). For example, when the detector 61 detects predetermined magnitude or more of displacement, the imaging determination section 52A determines to perform imaging. When the imaging determination section 52A determines not to perform imaging, the operation returns to the step S101.

When the imaging determination section 52A determines to perform imaging, a signal is inputted from the imaging determination section 52A to the imaging mode selector 52B, and the imaging mode selector 52B selects an optimum imaging mode corresponding to a situation (step S107). The controller 52 inputs a control signal to the driving section 51 on the basis of information from the imaging mode selector 52B, and the driving section 51 inputs a drive signal to each of the pixels 50 of the pixel section 50P on the basis of the control signal (step S104). Thus, imaging is performed (step S105), and an image is acquired. After acquiring the image, a surveillant determines whether or not to perform monitoring by the imaging device 1E. When monitoring is continued to be performed, the operation returns to the step S101. When monitoring is stopped after acquiring the image, the operation of the imaging device 1E ends.

Even in the present modification example, the MEMS 20 including the movable section 22 is provided to be stacked on the imaging element 10, which makes it possible to reduce the occupied area. In addition, displacement of the movable section 22 and the imaging operation of the imaging element 10 are linked with each other, which makes it possible to suitably use the imaging device 1D for monitoring. Furthermore, the controller 52 includes the imaging determination section 52A, which makes it possible to cause the imaging element 10 to perform the imaging operation only when the detector 61 detects abnormality. This makes it possible to reduce power consumption in the imaging device 1D, as compared with a case where the imaging element 10 constantly performs the imaging operation. In addition, the controller 52 includes the imaging mode selector 52B, which makes it possible to acquire an image with use of an optimum imaging mode corresponding to a situation.

### Modification Example 6

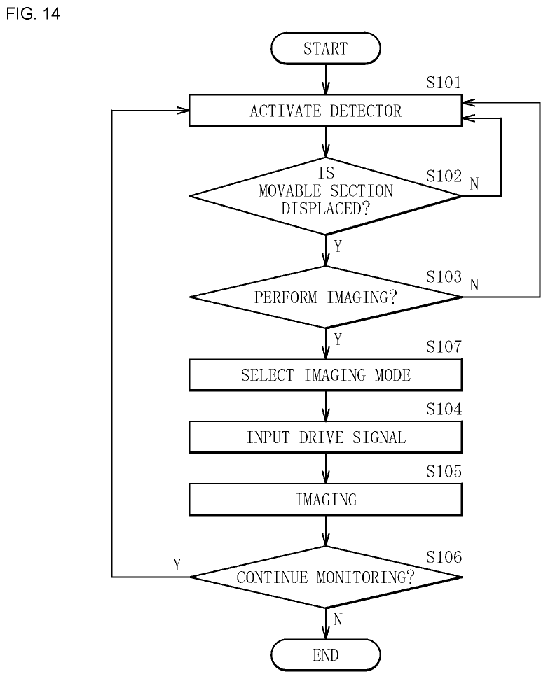

FIG. 15 illustrates a functional configuration of an imaging device (an imaging device 1F) according to a modification example 6 of the first embodiment described above. In the imaging device 1F, the controller 52 includes an imaging mode switching determination section 52C. The imaging device 1F according to the modification example 2 has a configuration similar to that of the imaging device 1 according to the first embodiment described above except for this point, and also attains similar workings and similar effects. FIG. 15 corresponds to FIG. 2 illustrating the imaging device 1.

The imaging device 1F is used, for example, for monitoring as with the imaging device 1D described above, and includes the detector 61 that detects displacement of the movable section 22. The detector 61 transmits a detection signal based on the displacement of the movable section 22 to the imaging mode switching determination section 52C. The imaging mode switching determination section 52C determines, by the detection signal transmitted from the detector 61, whether or not switching of the imaging mode is necessary. For example, the imaging mode switching determination section 52C determines whether or not switching from a moving image shooting mode to a still image shooting mode is necessary. When the imaging mode switching determination section 52C determines to perform switching of the imaging mode, the driving section 51 changes, on the basis of a control signal from the controller 52, a drive signal that is to be transmitted to each of the pixels 50 of the pixel section 50P.

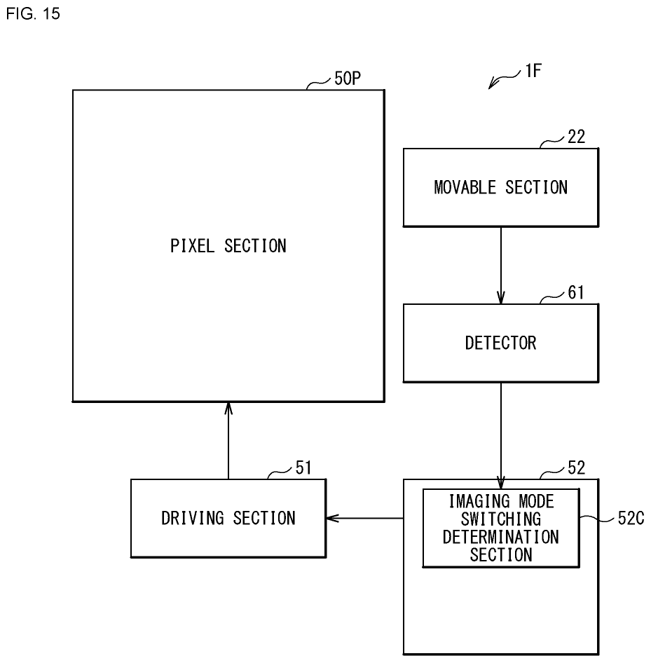

FIG. 16 illustrates an example of an operation of the imaging device 1F.

First, a pixel section 60P and the detector 61 are activated (step S201). For example, this causes the imaging element 10 to start to acquire an image in a moving image mode, and causes the detector 61 to monitor displacement of the movable section 22. Next, the detector 61 determines whether or not the movable section 22 is displaced (step S202). When the detector 61 detects displacement of the movable section 22, the detector 61 further determines whether or not the magnitude of the displacement is equal to or more than predetermined magnitude (step S203). When the magnitude of the displacement of the movable section 22 is equal to or more than the predetermined magnitude, a detection signal based on this displacement is inputted to the imaging mode switching determination section 52C. The imaging mode switching determination section 52C determines, on the basis of the detection signal from the detector 61, to switch the imaging mode from the moving image shooting mode to the still image shooting mode.

When the imaging mode switching determination section 52C determines to perform switching of the imaging mode, the driving section 51 changes, on the basis of a control signal from the controller 52, a drive signal that is to be transmitted to each of the pixels 50 of the pixel section 50P. This causes switching from the moving image shooting mode to the still image shooting mode to be performed (step S204), and a still image is acquired (step S205). The still image has, for example, high resolution, and is acquired at high scan speed. After acquiring the still image, a surveillant determines whether or not to perform monitoring by the imaging device 1F. When monitoring is continued to be performed, the operation returns to the step S201. When monitoring is stopped after acquiring the image, the operation of the imaging device 1F ends.

Even in the present modification example, the MEMS 20 including the movable section 22 is provided to be stacked on the imaging element 10, which makes it possible to reduce the occupied area. In addition, displacement of the movable section 22 and the imaging operation of the imaging element 10 are linked with each other, which makes it possible to suitably use the imaging device 1D for monitoring. Furthermore, the controller 52 includes the imaging mode switching determination section 52C, which allows the imaging element 10 to perform a still image capturing operation with high resolution at high scan speed only when the movable section 22 is displaced by the predetermined magnitude or more. This makes it possible for the imaging device 1F to acquire a high-image-quality image with less influence of vibration when abnormality occurs, as compared with a case where the imaging element 10 constantly performs an moving image capturing operation.

### Modification Example 7

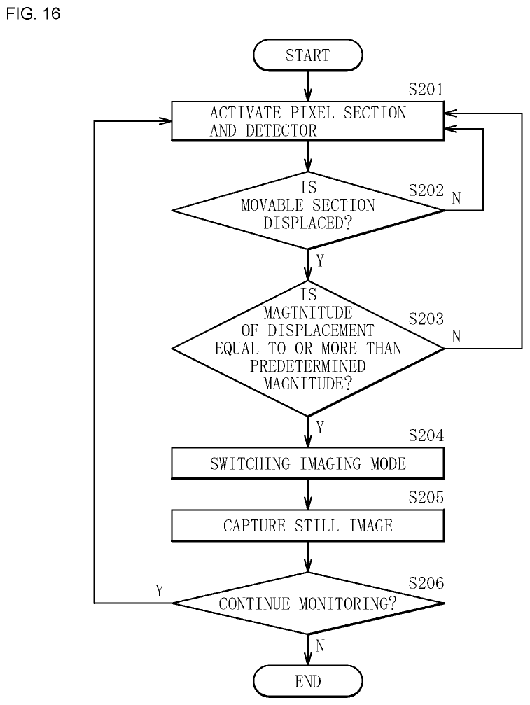

FIG. 17 illustrates an example of a configuration of a MEMS (a MEMS 20G) of an imaging device (an imaging device 1G) according to a modification example 7 of the first embodiment described above. The imaging device 1G includes the MEMS 20G that serves as a magnetic sensor. That is, in the MEMS 20G, the movable section 22 is displaced in accordance with a magnetic field. The imaging device 1G according to the modification example 7 has a configuration similar to that of the imaging device 1 according to the first embodiment described above except for this point, and also attains similar workings and similar effects.

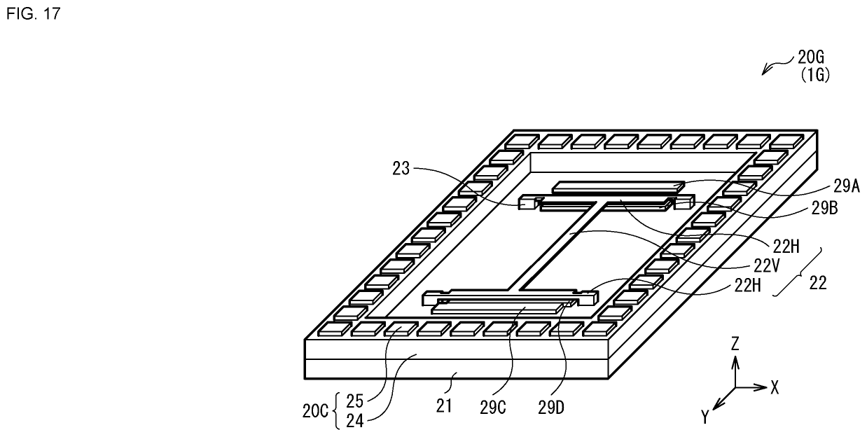

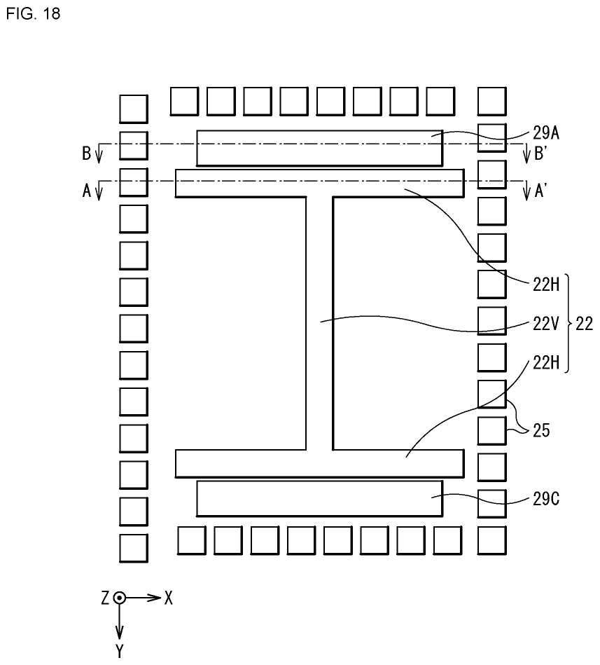

FIG. 18 schematically illustrates a planar configuration of the MEMS 20G illustrated in FIG. 17, and FIGS. 19A and 19B each schematically illustrate a cross-sectional configuration of the MEMS 20G. FIG. 19A illustrates a cross-sectional configuration taken along a line A-A′ illustrated in FIG. 18, and FIG. 19B illustrates a cross-sectional configuration taken along a line B-B′ illustrated in FIG. 18. In the MEMS 20G, the movable section 22 is displaced in accordance with the magnitude and the direction of a magnetic field (a magnetic field). The MEMS 20G includes, for example, electrodes 29A, 29B, 29C, and 29D in addition to the support substrate 21, the movable section 22, the fixing section 23, the surrounding wall 24, and the pad electrode 25 (FIGS. 17 and 18). The surrounding wall 24 has, for example, a stacked structure of a first surrounding wall 24A on side of the pad electrode 25, and a second surrounding wall 24B between the first surrounding wall 24A and the support substrate 21. The MEMS 20G includes, for example, a capacitive Lorentz force magnetic sensor.

The movable section 22 includes, for example, two horizontal-direction extending portions 22H and one vertical-direction extending portion 22V. The two horizontal-direction extending portions 22H are provided substantially in parallel, and linearly extend in the X-axis direction. The vertical-direction extending portion 22V is provided to couple middle sections of the horizontal-direction extending portions 22H, and linearly extends in a Y-axis direction. For example, both ends in the extending direction of each of the two horizontal-direction extending portions 22H are fixed to the support substrate 21 by the fixing section 23. The movable section 22 includes, for example, silicon (Si) or the like.

The electrodes 29A, 29B, 29C, and 29D are linear electrodes extending substantially in parallel with the horizontal-direction extending portions 22H. The electrodes 29A and 29B are disposed in proximity to one of the horizontal-direction extending portions 22H, and the electrodes 29C and 29D are disposed in proximity to the other of the horizontal-direction extending portions 22H. The electrodes 29A and 29C are disposed at positions not overlapping the horizontal-direction extending portions 22H in a plan view, and the electrode 29A and the electrode 29C are opposed to each other with the two horizontal-direction extending portions 22H and the vertical-direction extending portion 22V interposed therebetween. Thicknesses of the electrodes 29A and 29C are larger than thicknesses of the electrodes 29B and 29D, and top surfaces (surfaces opposite to surfaces on side of the support substrate 21) of the electrodes 29A and 29C are disposed at substantially the same positions in the thickness direction (the Z-axis direction) as a top surface of the movable section 22. The electrodes 29B and 29D are disposed at positions overlapping the horizontal-direction extending portions 22H in a plan view (FIG. 17). Sizes in the extending direction (the X-axis direction) of the electrodes 29B and 29D are smaller than those of the horizontal-direction extending portions 22H, and the electrodes 29B and 29D are disposed between the horizontal-direction extending portions 22H and the support substrate 21. The electrodes 29A, 29B, 29C, and 29D include, for example, silicon (Si) or the like.

An insulating film 231 is disposed between each of the electrodes 29A, 29B, 29C, and 29D and the support substrate 21. The insulating film 231 includes, for example, silicon oxide (SiO) or the like.

The surrounding wall 24 includes, for example, the second surrounding wall 24B and the first surrounding wall 24A in order from side of the support substrate 21. The first surrounding wall 24A includes, for example, the same material as a constituent material of the movable section 22. The second surrounding wall 24B includes, for example, the same material as a constituent material of the fixing section 23.

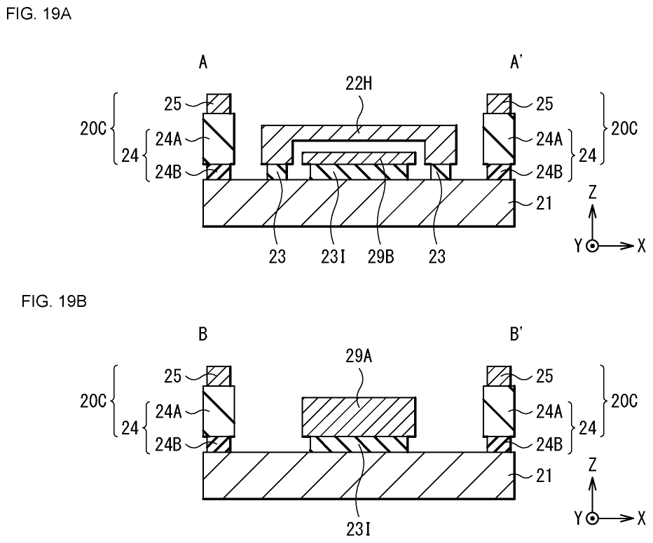

An example of a method of manufacturing such a MEMS 20G is described with use of FIGS. 20A to 23B. FIGS. 20A, 21A, and 22A each illustrate a process of manufacturing a portion corresponding to a cross section taken along a line A-A′ in FIG. 18, and FIGS. 20B, 21B, and 22B each illustrate a process of manufacturing a portion corresponding to a cross section taken along a line B-B′ in FIG. 18.

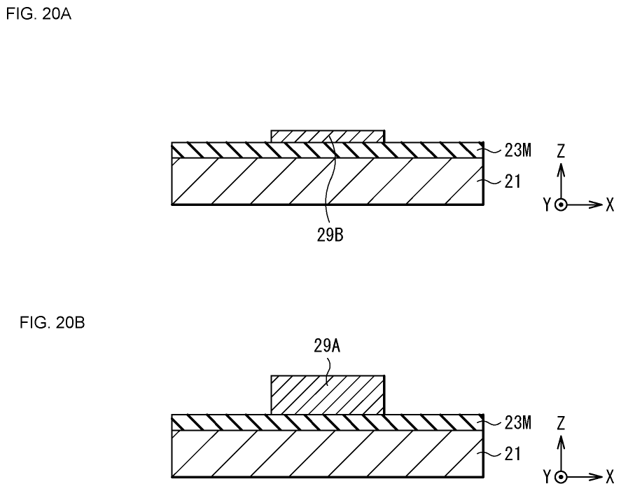

First, as illustrated in FIGS. 20A and 20B, an insulating film 23M and the electrodes 29A, 29B, 29C, and 29D are formed in this order on the support substrate 21 (the electrodes 29C and 29D are not illustrated, the same applies to FIGS. 21A to 23B). At this time, the thicknesses of the electrodes 29A and 29C are larger than the thicknesses of the electrodes 29B and 29D.

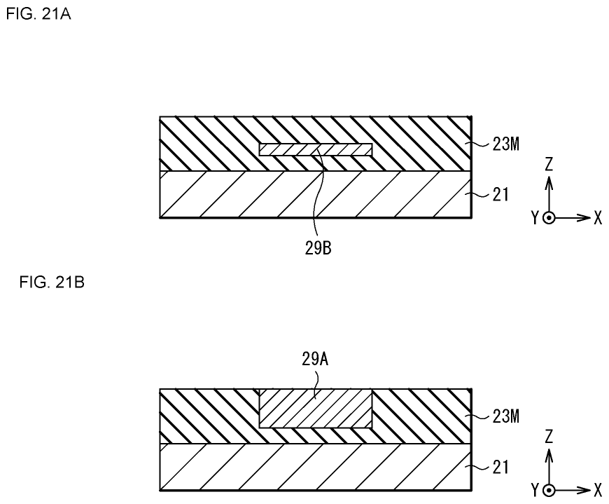

Next, as illustrated in FIGS. 21A and 21B, the insulating film 23M is formed to cover the electrodes 29B and 29D. Subsequently, as illustrated in FIGS. 22A and 22B, the movable section 22 and the first surrounding wall 24A are formed. The movable section 22 and the first surrounding wall 24A may be formed by the same process.

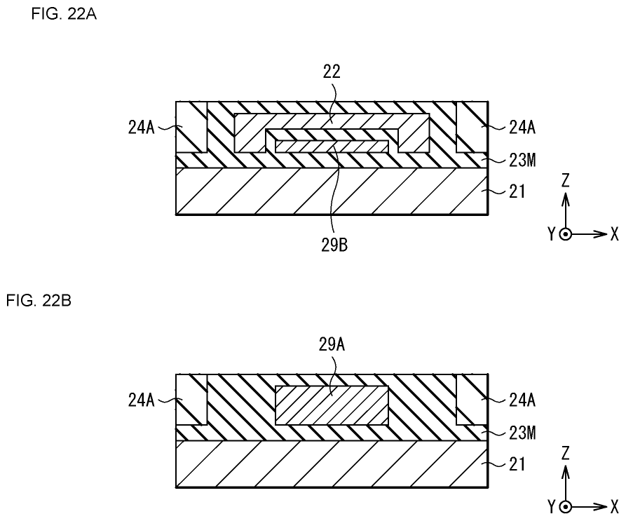

Thereafter, as illustrated in FIGS. 23A and 23B, the pad electrodes 25 are formed on the first surrounding wall 24A. After the pad electrodes 25 are formed, anisotropic etching and isotropic etching of the insulating film 23M are performed in this order. This removes an unnecessary portion of the insulating film 23M to form the fixing section 23, the second surrounding wall 23B, and the insulating film 231. Thus, it is possible to form the MEMS 20G, for example.

FIG. 24 illustrates an example of a functional configuration of the imaging device 1G. The imaging device 1G includes, for example, the signal processor 62 that processes a signal transmitted from the detector 61. The signal processor 62 may include, for example, an imaging-direction specifying section 62A. The imaging-direction specifying section 62A specifies a direction of the light-receiving surface (the light-receiving surface S1 in FIG. 1 and the like) by a direction of displacement of the movable section 22 detected by the detector 61, for example. As described in detail later, the imaging device 1G including such an imaging-direction specifying section 62A makes it possible to easily specify a shooting direction of the imaging device 1G even when the imaging device 1G is in a stationary state or the like.

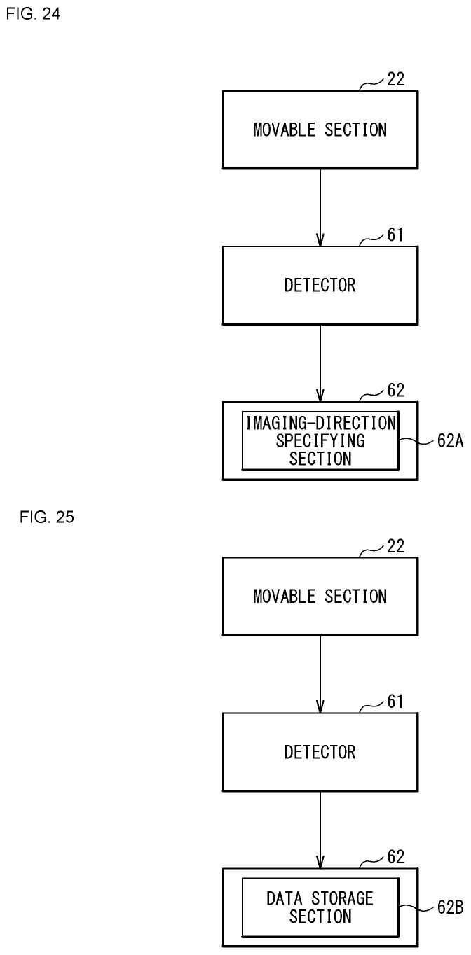

FIG. 25 illustrates another example of the functional configuration of the imaging device 1G. The signal processor 62 may include a data storage section 62B. In the data storage section 62B, for example, information about displacement of the movable section 22, that is, information about the magnitude of a magnetic field and the direction of the magnetic field is stored through the detector 61 at predetermined time intervals. This makes it possible for the imaging device 1G to specify time change in the magnetic field.

Even in the present modification example, the MEMS 20G including the movable section 22 is provided to be stacked on the imaging element 10, which makes it possible to reduce the occupied area. In addition, the MEMS 20G that serves as a magnetic sensor is stacked on the imaging element 10, which makes it possible to easily specify a shooting location and the direction of the light-receiving surface (the light-receiving surface S1 in FIG. 1 and the like) even in a case where the imaging device 1G is in the stationary state. Workings and effects thereof are described below.

For example, as a method of specifying the shooting location of the imaging device and the direction of the light-receiving surface, using a global positioning system (GPS: Global Positioning System) may be considered. However, the GPS is able to specify the shooting location and the direction of the light-receiving surface when the imaging device is in a moving state, but is not able to specify the shooting location and the direction of the light-receiving surface when the imaging device is in the stationary state. In addition, the GPS is not also able to specify the shooting location and the direction of the light-receiving surface when the imaging device is located at a position where the GPS is not able to receive a GPS signal. Meanwhile, the imaging device includes a plurality of sensors such as a gyro sensor, an acceleration sensor, and a geomagnetic sensor, which makes it possible to specify the shooting location and the direction of the light-receiving surface even in a case where positioning information using the GPS is not available. However, in this case, a plurality of sensors are necessary, which results in difficulty in downsizing of the imaging device. In addition, in a case where the imaging element and the geomagnetic sensor are coupled to each other by a wiring substrate or the like, the direction of the imaging element and the direction of the geomagnetic sensor may be deviated. It is therefore difficult to directly use information acquired from the geomagnetic sensor to specify the direction of the light-receiving surface.

In contrast, in the imaging device 1G, The MEMS 20G serving as a magnetic sensor is stacked on the imaging element 10, thereby acquiring information about geomagnetism by the MEMS 20G. Accordingly, even in a case where the positioning information with use of the GPS is not available, it is possible to specify the shooting location of the imaging device 1G and the direction of the light-receiving surface. For example, the imaging device 1G includes the imaging-direction specifying section 62A, which allows a photographer to easily specify the shooting direction. It is possible to use the specification of the shooting direction as follows, for example. Some map information available on the Web is provided with a shot image. A user is able to post a shot image of which the shooting direction is specified, together with position information. The shooting direction is designated by an arrow (→) symbol on the Web, for example. Using the imaging device 1G makes it possible to automatically add the shooting direction on the Web.

In addition, in the imaging device 1G, it is possible to easily specify the shooting direction even in a case where a photographer is not able to visually recognize the imaging device 1G. For example, the imaging device 1G is suitably applicable to an endoscope and the like. Even in a case where the photographer is not able to visually recognize the imaging device 1G, a magnetic force is applied from outside, and the MEMS 20G (the detector 61) detects the magnetic force to thereby specify the shooting direction (the direction of the light-receiving surface of the imaging device 1G).

In addition, the imaging device 1G includes the MEMS 20G serving as a magnetic sensor, which makes it possible to specify the shooting location and the direction of the light-receiving surface without including a plurality of sensors. This makes it possible to downsize the imaging device 1G.

Furthermore, the imaging device 1G includes the data storage section 62B, which makes it possible to measure time change in geomagnetism. For example, the imaging device 1G is suitably applicable to a wearable camera (a portable camera) for watching seniors or crime prevention for children. In this case, even if it is not possible to secure sufficient illumination for shooting, it is possible to specify time transition of a direction of geomagnetism by the MEMS 20G, which easily predicts the action of a wearer of the wearable camera.

### Second Embodiment

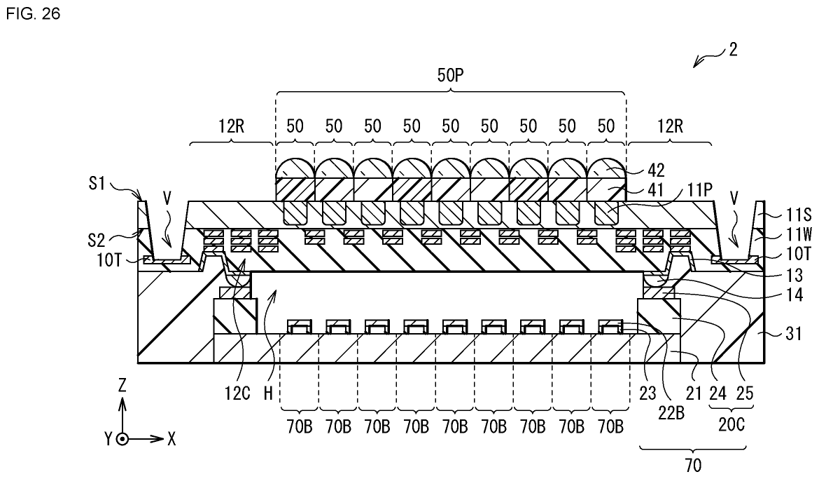

FIG. 26 illustrates a schematic cross-sectional configuration of a main part of an imaging device (an imaging device 2) according to a second embodiment of the present disclosure. In the imaging device 2, an infrared detector 70 is stacked on the imaging element 10. Here, the infrared detector 70 corresponds to a specific example of an electronic element of the present disclosure. The imaging device 2 according to the second embodiment has a configuration similar to that of the imaging device 1 according to the first embodiment described above except for this point, and also attains similar workings and similar effects. FIG. 26 corresponds to (A) of FIG. 1 illustrating the imaging device 1.

The imaging element 10 includes a logic circuit section 12R outside the pixel section 50P in place of the logic chip (the logic chip 12 in (A) of FIG. 1). That is, the imaging element 10 of the imaging device 2 is a non-stacking type imaging element.

The infrared detector 70 includes, for example, a detection film 22B in place of the movable section (the movable section 22 in (A) of FIG. 1). The detection film 22B is provided to detect light of a wavelength in an infrared region (e.g., a wavelength of 5 μm to 8 μm), and includes, for example, a bolometer film or the like. It is possible to use, for example, vanadium oxide (VO), titanium oxide (TiO), or the like for the detection film 22B. Here, the detection film 22B corresponds to a specific example of a floating section of the present disclosure.

The detection film 22B is provided to be spaced apart from the support substrate 21 and the imaging element 10 (the multilayer wiring layer 11W), and is fixed to the support substrate 21 by the fixing section 23. For example, the fixing section 23 fixes the proximity of a periphery of the detection film 22B to the support substrate 21. The infrared detector 70 includes, for example, a plurality of detection films 22B. In the infrared detector 70, a plurality of coupling sections 20C is provided to surround the plurality of detection films 22B in a plan view. The pad electrode 25 of the coupling section 20C is electrically coupled to the multilayer wiring layer 11W through the microbump 14 and the rewiring layer 13. The imaging device 2 includes a resin layer 31 around the infrared detector 70.

The plurality of detection films 22B is disposed, for example, in the infrared detector 70 for respective detection unit regions 70B. For example, one detection unit region 70B is disposed corresponding to one pixel 50, for example.

FIG. 27A illustrates an example of a planar configuration of the imaging element 10, and FIG. 27B illustrates an example of a planar configuration of the infrared detector 70. FIGS. 27A and 27B illustrate a region corresponding to four pixels 50 (four detection unit regions 70B).

In the imaging element 10, pixel transistors Tr1, Tr2, Tr3, and Tr4 are provided around each PD 11P. Examples of the pixel transistors Tr1, Tr2, Tr3, and Tr4 include a transfer transistor, a reset transistor, an amplifier transistor, a selection transistor, and the like. In the imaging element 10, the pixel drive lines L2, L3, and L4 are wired along the row direction for each pixel row, and the vertical signal line L1 is wired along the column direction for each pixel column. Wiring lines of the imaging element 10 are preferably provided to avoid a region overlapping the detection film 22B in a plan view. This allows light of a wavelength in the infrared region to efficiently enter the infrared detector 70.

In the infrared detector 70, a readout circuit 71 is provided around the detection film 22B. In the infrared detector 70, a drive line L6 is provided in parallel with the pixel drive lines L2, L3, and L4, and a signal line L5 is provided in parallel with the vertical signal line L1. For example, the center of the detection film 22B is disposed at a position overlapping a substantial center of the PD 11P in a plan view.

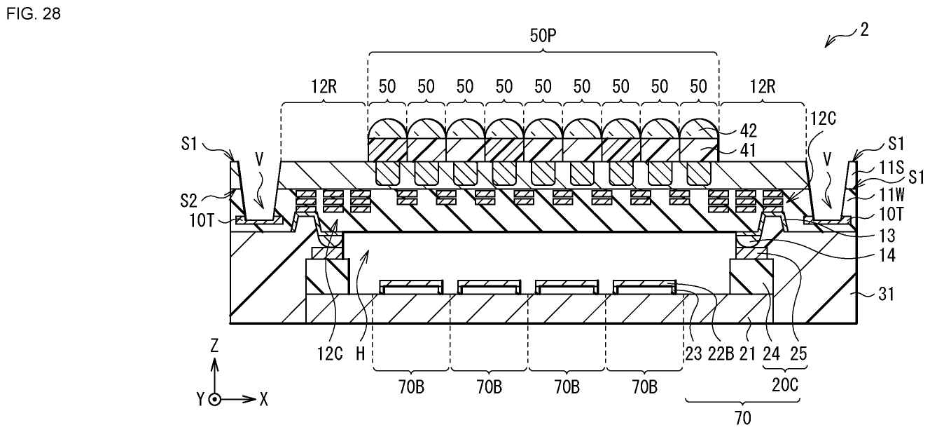

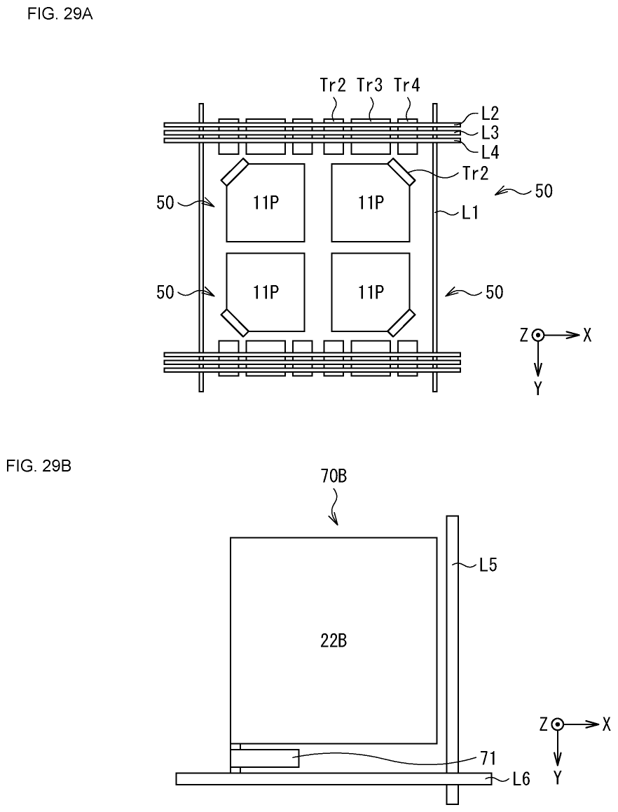

FIG. 28 illustrates another example of the cross-sectional configuration of the imaging device 2 illustrated in FIG. 27. FIG. 29A illustrates an example of a planar configuration of the imaging element 10 illustrated in FIG. 28, and FIG. 29B illustrates an example of a planar configuration of the infrared detector 70 illustrated in FIG. 28. FIGS. 27A and 27B illustrate a region corresponding to four pixels 50 (one detection unit region 70B). One detection unit region 70B (one detection film 22B) may be disposed corresponding to a plurality of pixels 50 in such a manner. FIGS. 28, 29A, and 29B illustrate an example in which one detection unit region 70B is disposed corresponding to four pixels 50. At this time, for example, the center of the detection film 22B is disposed, for example, at a position overlapping a substantial center of four PDs 11P in a plan view, and wiring lines of the imaging element 10 are preferably provided around the four PDs 11P. Disposing one detection unit region 70B corresponding to a plurality of pixels 50 makes it possible to design the area of the detection film 22B irrespective of the size of the pixel 50. Thus, miniaturization of the pixel 50 and an improvement in sensitivity of the infrared detector 70 are easily made compatible.

Even in the imaging device 2 according to the present embodiment, the infrared detector 70 including the detection films 22B is provided to be stacked on the imaging element 10, which makes it possible to reduce the occupied area. In addition, in the imaging device 2, it is possible to design the size of the detection unit region 70B irrespective of the size of the pixel 50. Thus, miniaturization of the pixel 50 and an improvement in sensitivity of the infrared detector 70 are easily made compatible.

### <Practical Application Example to In-Vivo Information Acquisition System>

Further, the technology (present technology) according to the present disclosure is applicable to various products. For example, the technology according to the present disclosure may be applied to an endoscopic surgery system.

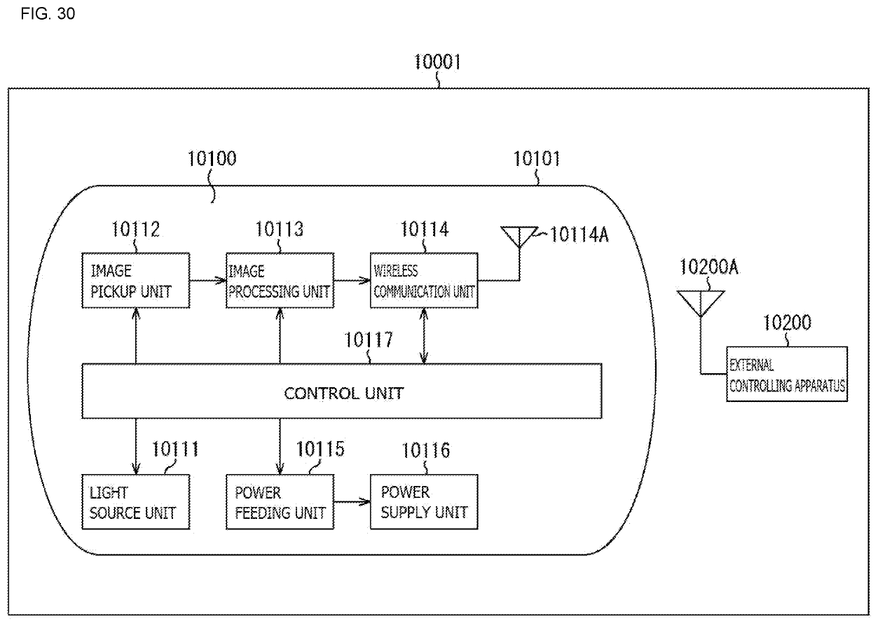

FIG. 30 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 30, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

One example of the in-vivo information acquisition system to which the technology according to the present disclosure is applicable has been described above. The technology according to the present disclosure is applicable to, for example, the image pickup unit 10112 of the configurations described above. This makes it possible to improve accuracy of an inspection.

### <Practical Application Example to Endoscopic Surgery System>

The technology (present technology) according to the present disclosure is applicable to various products. For example, the technology according to the present disclosure may be applied to an endoscopic surgery system.

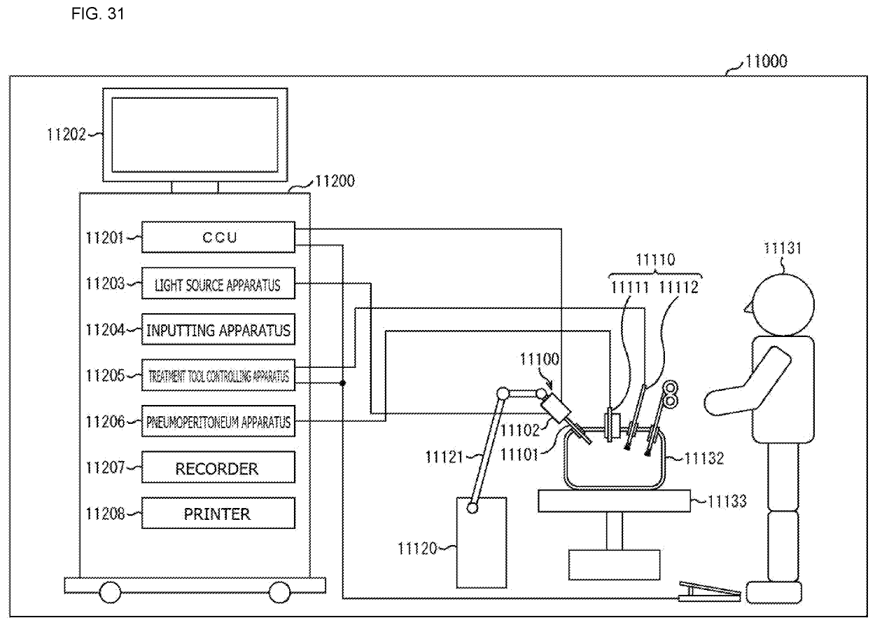

FIG. 31 is a view depicting an example of a schematic configuration of an endoscopic surgery system to which the technology according to an embodiment of the present disclosure (present technology) can be applied.

In FIG. 31, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

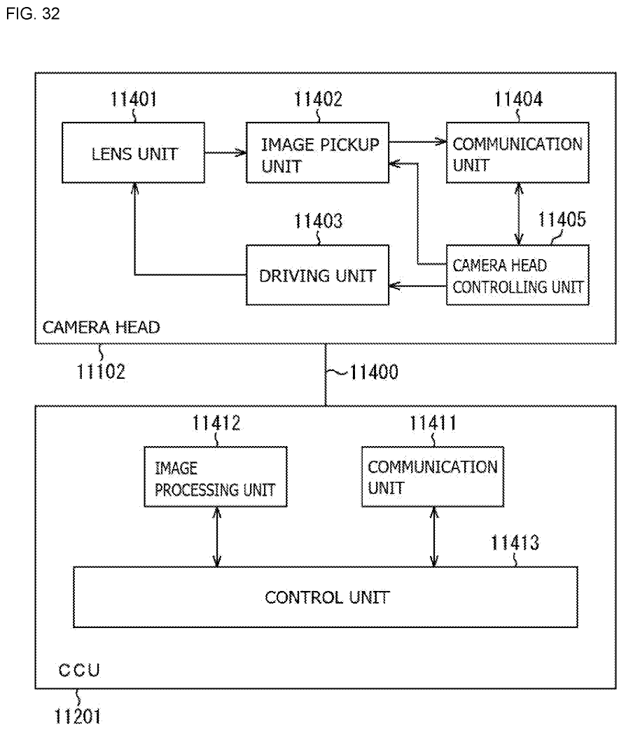

FIG. 32 is a block diagram depicting an example of a functional configuration of the camera head 11102 and the CCU 11201 depicted in FIG. 31.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure is applicable has been described above. The technology according to the present disclosure is applicable to, for example, the image pickup unit 11402 of the configurations described above. Applying the technology according to the present disclosure to the image pickup unit 11402 makes it possible to improve accuracy of an inspection.

It is to be noted that the endoscopic surgery system has been described here as an example, but the technology according to the present disclosure may be additionally applied to, for example, a microscopic surgery system and the like.

### <Practical Application Example to Mobile Body>

The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

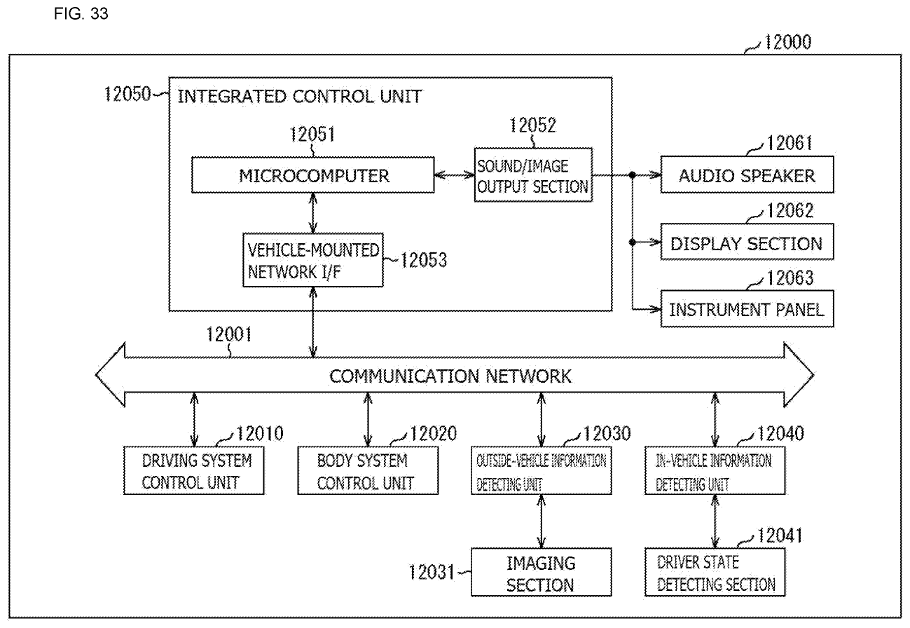

FIG. 33 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 33, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 33, an audio speaker 12061, a display section 12062, and an instrument panel 12063 are illustrated as the output device. The display section 12062 may, for example, include at least one of an on-board display and a head-up display.

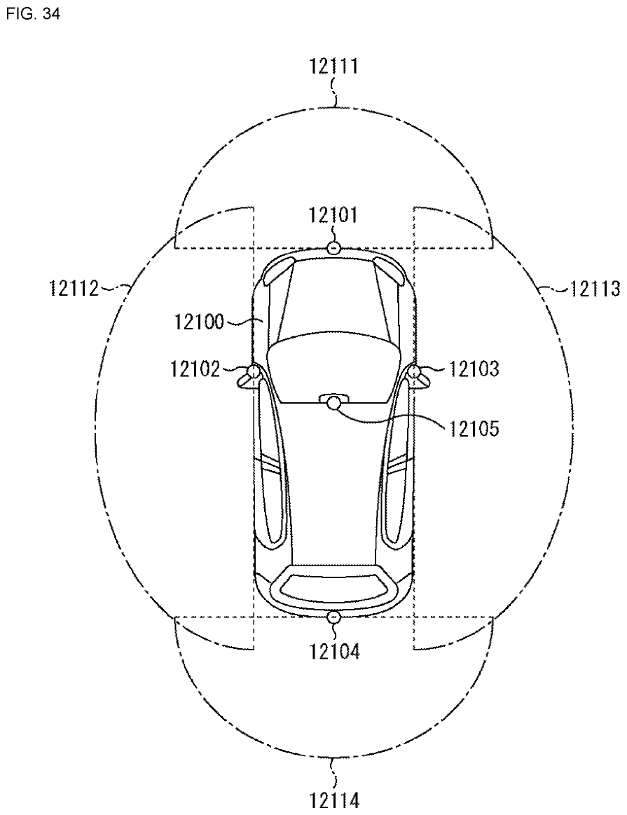

FIG. 34 is a diagram depicting an example of the installation position of the imaging section 12031.

In FIG. 34, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 34 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure is applicable has been described above. The technology according to the present disclosure is applicable to the imaging section 12031 of the configurations described above. Applying the technology according to the present disclosure to the imaging section 12031 makes it possible to obtain a shot image that is easier to see. This makes it possible to decrease the fatigue of a driver.

The present disclosure has been described above with reference to the embodiments and the modification examples, but the contents of the present disclosure are not limited to the embodiments described above, and may be modified in a variety of ways. For example, the configuration of the imaging device described in any of the embodiments and the like described above is an example, and other layers may be further included. In addition, the material and thickness of each layer are also examples, and are not limited to those described above.

In addition, in the embodiments and the like described above, description has been given of an example in which the imaging element 10 includes the sensor chip 11 and the logic chip 12 (or the logic circuit section 12R), but the imaging element 10 may further include a chip having another function, or may have a chip having another function in place of the logic chip 12.

In addition, in the embodiments and the like described above, description has been given of an example in which the imaging element 10 is a back-illuminated imaging element, but the imaging element 10 may be a front-illuminated imaging element. Alternatively, the imaging element 10 may be an imaging element using an organic semiconductor.

In addition, an example of the configuration of the MEMS 20 is illustrated in FIG. 1 and the like, but the MEMS 20 may have any other configuration.

The effects described in the embodiments and the like described above are examples, and the effects may be other effects or may further include other effects.

It is to be noted that the present disclosure may have the following configurations. According to the present technology having the following configurations, an electric element including a floating section is provided to be stacked on an imaging element, which makes it possible to reduce an occupied area, as compared with a case where an imaging section and an electric element section including a floating section are provided side by side. This makes it possible to reduce the occupied area.

(1)

An imaging device including:

an imaging element provided with a photoelectric converter for each pixel, and having a light-receiving surface and a non-light-receiving surface opposed to the light-receiving surface; and

an electric element including a support substrate and a floating section, the support substrate provided on side of the non-light-receiving surface of the imaging element and opposed to the imaging element, and the floating section provided between the support substrate and the imaging element, and disposed with a gap interposed between the floating section and each of the support substrate and the imaging element.

(2)

The imaging device according to (1), further including:

a plurality of coupling sections that is provided around the floating section and couples the support substrate and the imaging element to each other, in which

the floating section is provided in a hollow section surrounded by the imaging element, the support substrate, and the plurality of coupling sections.

(3)

The imaging device according to (2), in which each of the plurality of the coupling sections includes a pad electrode of the electric element, the pad electrode being provided at a position closer, in a direction of stacking the electric element and the imaging element, to the imaging element than the floating section, and being electrically coupled to the imaging element.

(4)

The imaging device according to (3), in which the pad electrodes include a dummy.

(5)

The imaging device according to any one of (2) to (4), further including a resin layer surrounding the coupling sections.

(6)

The imaging device according to any one of (1) to (5), in which the floating section includes a movable section.

(7)

The imaging device according to (6), further including:

a driving section that drives each of the pixels; and

a controller that inputs a control signal to the driving section.

(8)

The imaging device according to (7), further including a detector that detects displacement of the movable section, in which

the controller inputs the control signal to the driving section on the basis of a detection signal transmitted from the detector.

(9)

The imaging device according to (8), in which

the controller includes an imaging determination section, and

the controller inputs the control signal to the driving section on the basis of a detection signal transmitted from the detector to the imaging determination section.

(10)

The imaging device according to (9), in which, in a case where magnitude of displacement of the movable section detected by the detector is equal to or more than predetermined magnitude, the controller drives each of the pixels by the control signal.

(11)

The imaging device according to (8), in which the controller includes an imaging mode switching determination section that determines whether or not switching of an imaging mode is necessary.

(12)

The imaging device according to (8), in which the controller includes an imaging mode selector that selects an imaging mode.

(13)

The imaging device according to any one of (1) to (8), in which the electric element includes a magnetic sensor in which the floating section is displaced in accordance with a magnetic field.

(14)

The imaging device according to (13), further including an imaging-direction specifying section that specifies a direction of the light-receiving surface of the imaging element by a direction of a magnetic field detected by the magnetic sensor.

(15)

The imaging device according to (13), further including a data storage section that stores information about a magnetic field detected by the magnetic sensor.

(16)

The imaging device according to any one of (1) to (15), in which the imaging element includes a first semiconductor substrate and a multilayer wiring layer from side of the light-receiving surface, the first semiconductor substrate being provided with the photoelectric converter, and the multilayer wiring layer being stacked on the first semiconductor substrate and including a wiring line electrically coupled to the photoelectric converter.

(17)

The imaging device according to (16), in which the imaging element further includes a second semiconductor substrate that is provided between the multilayer wiring layer and the electric element and is electrically coupled to the first semiconductor substrate through the multilayer wiring layer.

(18)

The imaging device according to any one of (1) to (5), in which the floating section includes a bolometer film.

(19)

The imaging device according to (18), in which

the electric element includes a plurality of the floating sections, and

one of the floating sections is disposed in a region corresponding to a plurality of the pixels.

This application claims the benefit of Japanese Priority Patent Application JP2019-056134 filed with Japan Patent Office on Mar. 25, 2019, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
an imaging element provided with a photoelectric converter for each pixel, and having a light-receiving surface and a non-light-receiving surface opposed to the light-receiving surface; and
an electric element including a support substrate and a floating section, the support substrate provided on side of the non-light-receiving surface of the imaging element and opposed to the imaging element, and the floating section provided between the support substrate and the imaging element, and disposed with a gap interposed between the floating section and each of the support substrate and the imaging element.

2. The imaging device according to claim 1, further comprising:
a plurality of coupling sections that is provided around the floating section and couples the support substrate and the imaging element to each other, wherein
the floating section is provided in a hollow section surrounded by the imaging element, the support substrate, and the plurality of coupling sections.

3. The imaging device according to claim 2, wherein each of the plurality of the coupling sections includes a pad electrode of the electric element, the pad electrode being provided at a position closer, in a direction of stacking the electric element and the imaging element, to the imaging element than the floating section, and being electrically coupled to the imaging element.

4. The imaging device according to claim 3, wherein the pad electrodes include a dummy.

5. The imaging device according to claim 2, further comprising a resin layer surrounding the coupling sections.

6. The imaging device according to claim 1, wherein the floating section comprises a movable section.

7. The imaging device according to claim 6, further comprising:
a driving section that drives each of the pixels; and
a controller that inputs a control signal to the driving section.

8. The imaging device according to claim 7, further comprising a detector that detects displacement of the movable section, wherein
the controller inputs the control signal to the driving section on a basis of a detection signal transmitted from the detector.

9. The imaging device according to claim 8, wherein
the controller includes an imaging determination section, and
the controller inputs the control signal to the driving section on a basis of a detection signal transmitted from the detector to the imaging determination section.

10. The imaging device according to claim 9, wherein, in a case where magnitude of displacement of the movable section detected by the detector is equal to or more than predetermined magnitude, the controller drives each of the pixels by the control signal.

11. The imaging device according to claim 8, wherein the controller includes an imaging mode switching determination section that determines whether or not switching of an imaging mode is necessary.

12. The imaging device according to claim 8, wherein the controller includes an imaging mode selector that selects an imaging mode.

13. The imaging device according to claim 1, wherein the electric element comprises a magnetic sensor in which the floating section is displaced in accordance with a magnetic field.

14. The imaging device according to claim 13, further comprising an imaging-direction specifying section that specifies a direction of the light-receiving surface of the imaging element by a direction of a magnetic field detected by the magnetic sensor.

15. The imaging device according to claim 13, further comprising a data storage section that stores information about a magnetic field detected by the magnetic sensor.

16. The imaging device according to claim 1, wherein the imaging element includes a first semiconductor substrate and a multilayer wiring layer from side of the light-receiving surface, the first semiconductor substrate being provided with the photoelectric converter, and the multilayer wiring layer being stacked on the first semiconductor substrate and including a wiring line electrically coupled to the photoelectric converter.

17. The imaging device according to claim 16, wherein the imaging element further includes a second semiconductor substrate that is provided between the multilayer wiring layer and the electric element and is electrically coupled to the first semiconductor substrate through the multilayer wiring layer.

18. The imaging device according to claim 1, wherein the floating section includes a bolometer film.

19. The imaging device according to claim 18, wherein
the electric element includes a plurality of the floating sections, and
one of the floating sections is disposed in a region corresponding to a plurality of the pixels.
